(19) United States
(12) Patent Application Publication
(10) Pub. No.: US 2025/0271508 A1
(43) Pub. Date: Aug. 28, 2025

(54) SYSTEM AND METHOD OF LOCATING A SHEATH TO GROUND FAULT IN ELECTRIC CABLES

(71) Applicant: INDIAN INSTITUTE OF TECHNOLOGY ROPAR, Rupnagar (IN)

(72) Inventors: Aritra DAS, Rupnagar (IN); Chakradhar Reddy CHANDUPATLA, Rupnagar (IN)

(73) Assignee: INDIAN INSTITUTE OF TECHNOLOGY ROPAR, Rupnagar (IN)

(21) Appl. No.: 18/647,131

(22) Filed: Apr. 26, 2024

(30) Foreign Application Priority Data
Feb. 27, 2024 (IN) 202411014305

(51) Int. Cl. G01R 31/52; G01R 31/08; G01R 31/58

(52) U.S. Cl. CPC G01R 31/52; G01R 31/083; G01R 31/58

(57) ABSTRACT

A method and a system for identifying and locating sheath-to-ground fault at any arbitrary locations in a cross-bonded, single point grounded at the beginning, single point grounded or at the end at the middle, and two point grounded power cable during online condition. The system comprises a circuit having a major section of high voltage cross-bonded cable having 3 phases R and three minor sections, which interconnected with SVLs in the link box to form three loops, three-phase source voltages, and loads of each phase. The metallic sheath of each phase is grounded at the grounding box through grounding resistances. A current measuring unit measures the sheath current from this grounding resistance. This measured current is analyzed to identify and localize the inception of SG fault in a CB cable.

### CROSS-REFERENCE TO RELATED APPLICATIONS AND PRIORITY

The present application claims benefit from Indian Patent Application No.: 202411014305 filed on 27 Feb. 2024 entirety of which is hereby incorporated by reference.

### TECHNICAL FIELD

The present subject matter described herein, in general, relates to a system and method of locating sheath to ground faults. More particularly, the present subject matter relates to a system of identifying and locating a sheath to ground (SG) fault at any arbitrary locations in cross-bonded (CB) as well in non-cross-bonded cables during online conditions.

### BACKGROUND

Conventional metallic sheath protects the cable's insulation from water ingress, provides mechanical strength, and acts as a return path for the capacitive and inductive current during healthy operating conditions and short-circuited fault conditions. For an HVAC cable, the metallic sheath of a particular phase has to be grounded in at least one point, and therefore, it acts as a shield that electrically isolates the particular phase from the remaining phases. Since the metallic sheath is grounded at one point, a continuous circulating current flows in the sheath, impacting the cable's ampacity. Therefore to reduce the losses in the metallic sheath due to circulating current, cross-bonding (CB) of the metallic sheath was introduced.

However, due to the expansion of urban areas, and to connect substations and consumers, short and medium-length power cables are used. For short to medium-length cables non-cross-bonded methods are used. According to IEEE standard 575, there are three types of bonding for short to medium-length HVAC power cables. The very basic type of bonding is the single point bonding at the beginning or the end. One end of the cable sheath is grounded with a grounding resistance while the other end is connected with a sheath voltage limiter (SVL). The second type of bonding is the single-point bonding at the middle of the cable. Both ends of the cable sheath are connected with SVLs while the grounding is provided at the middle of the cable using a grounding resistance. The third type of bonding is two-point bonding. Both the ends of the cable are grounded with grounded resistance. There are no SVLs used in this type of bonding.

In a CB cable system, the whole cable network is divided into major sections (the number of major sections depends on the total length of the cable network). Both ends of a major section are solidly grounded through grounding resistance (103) (in the grounding box). The CB of the metallic sheath is configured in these major section, therefore a major section will have three minor sections. The metallic sheath of one phase is CB with the other phase in the link box through a sheath voltage limiter (SVL) (107). A minute ground-to-sheath fault will cause a huge flow of circulating current in the sheath, which results in the premature breakdown of the insulation of the cable. Therefor condition monitoring of the cable sheath is of utmost importance for extending the lifespan of the cable

The condition of the metallic sheath deteriorated mainly due to its poor handling or maintenance, adverse climate conditions, and substandard workmanship. According to the published statistics of the last twenty years for a CB HV cable, most ground faults occur at link boxes, joints, and terminals. However, premature breakdown due to SG faults in the third minor section (106) is reported by a local utility sector for a 220 kV cable network of the Mumbai su-urban region of Maharashtra, India. Therefor to maintain the continuous power flow, estimation of the location of the sheath to a ground fault before the breakdown of cable at any arbitrary location is of paramount importance.

Since the metallic sheath of the CB cable and non-CB cable is grounded at the grounding boxes, therefore the study of sheath current and its voltage at different locations (grounding box and link box) is the only method for condition monitoring of the sheath. Estimation of the sheath current under normal operating conditions using numerical methods. The study of sheath current was utilized to detect the inception of the short-circuited fault [9] and insulation monitoring in a CB cable. However, the feasibility of identifying SG fault only at the ends of the cross-bonded section. Attempts were made to identify and localize the presence of a sheath fault at the link box only by measuring the sheath current from the preinstalled sensor at the link box.

Although the identification of the presence of sheath fault is accomplished from the measured sheath current at the link boxes, however, the pinpoint location at any arbitrary position is still unachievable. Along with this, installation of the current sensor into the link during operational conditions can prove to be hazardous for the maintenance workers, due to the presence of sudden switching impulses.

The sheath current mainly consists of inductive current due to load current, capacitive current, and leakage current. However, the value of the leakage current is always in nano-femto amperes (except during conductor-to-ground fault), and the cumulative sum of inductive and capacitive currents is in amperes. Therefor the value effect of leakage current is negligible in the measurement of sheath current. According to existing literature, the flow of capacitive current is difficult to calculate for a cross-bonded cable network. To estimate the pinpoint location of the SG fault, the exact value of inductive and capacitive current is extremely vital. In this article, a circuit theory model is used for the first time to estimate the effect of both the capacitive and inductive effect in sheath current both under normal operating conditions and SG fault. Finally, formulae are proposed by which the location of the sheath fault can be estimated from the measurement of the ground current only. The results are validated by simulation in a circuit simulation software and MATLAB Simulink as well as experiments on a power.

Earlier attempts were made to identify the presence or absence of any fault in the CB joints only. However, identifying the SG fault at any arbitrary location is still unachievable. Therefor first time a technique is developed by which the location of an SG fault at any arbitrary location can be identified with pin-point accuracy.

The present disclosure is directed to overcome one or more limitations stated above and any other limitations associated with the prior arts.

### OBJECT OF THE INVENTION

Main object of the present disclosure is to provide a method to identify and locate system-to-ground (SG) fault in a cross-bonded (CB) as well as in a non-CB cable and its pinpoint location can be identified only by measuring the currents in the grounding resistance (103) during online conditions.

Another object of the present disclosure is to provide the method to identify and locate system-to-ground (SG) fault in a cross-bonded (CB) as well as in a non-CB cable by using different analytical formulae through the dimension of the cable and electrical parameters to establish the different range of values to detect in which minor section the SG fault has taken place.

Yet another object of the present disclosure is to provide the method to identify and locate system-to-ground (SG) fault in a cross-bonded (CB) as well as in a non-CB cable that will work in any balanced or unbalanced condition in practical case (unbalancing in power supply, power factor, length, or dimension).

### SUMMARY

Before the present system and method of locating a sheath to ground faults in cross-bonded (CB) as well as in a non-CB cables are described, it is to be understood that this application is not limited to the particular systems, and methodologies described, as there can be multiple possible embodiments, which are not expressly illustrated in the present disclosure. It is also to be understood that the terminology used in the description is for the purpose of describing the particular versions or embodiments only, and is not intended to limit the scope of the present application. This summary is provided to introduce concepts related to the system and method of locating a sheath to ground faults in cross-bonded (CB) cables. This summary is not intended to identify essential features of the claimed subject matter nor is it intended for use in determining or limiting the scope of the claimed subject matter.

In one implementation, in a method (1200) of locating sheath-to-ground (SG) fault in a cross-bonded (CB) (111) power cable. The method (1200) estimates the location of the sheath-to-ground (SG) fault in a cross-bonded (CB) (111) in online condition by measuring the earthing current at the straight-through joints. Further, a system (100) creates a circuit model (500) of a CB cable (111), to estimate the grounding current analytically at its healthy operating condition. First, the range of grounding current is estimated for a cable having SG fault at different sections using the analytical method (1200) which is based on the proposed circuit model (500) of the CB cable (111). The measured grounding current is compared with the analytical current range, and if the measured current is in the proposed analytical range, the SG fault is confirmed and the location of the same is obtained by the proposed analytical formula. Both, simulations in MATLAB Simulink, as well as experiments on a test cable and on-filed operation, were performed to validate the proposed formulae.

In one implementation, in a method (1300) of locating sheath-to-ground (SG) fault in a non cross-bonded power cable. The method (1300) estimates the location of the sheath-to-ground (SG) fault in a non cross-bonded (CB) in single point grounded in the beginning or at the end (200), single point grounded at the middle (300), and two point grounded (400) in online condition by measuring the earthing current at the straight-through joints. Further, a system creates a circuit model for different types of bonding, to estimate the grounding current analytically at its healthy operating condition. First, the grounding current is estimated for a healthy cable having no fault, which is based on the proposed circuit model of the CB cable. The measured grounding current is compared with the analytical current range, and if the measured current does not match with the proposed analytical range, the SG fault is confirmed and the location of the same is obtained by the proposed analytical formula. Both, simulations in MATLAB Simulink, as well as experiments on a test cable.

In one implementation, in a system (100) for locating sheath-to-ground (SG) fault in a cross-bonded (CB) power cable (111). Further, the high voltage cross-bonded (CB) power cable (111) has 3 phases R (108), Y (109), and B (110). The system (100) comprises a circuit model (500) having a major section of CB cable (111). Where, L₁, L₂, and L₃ are the lengths of the three minor sections named Rⱼ, Yⱼ, and Bⱼ (j=1, 2, and 3 representing each minor section), interconnected with sheath voltage limiters (SVLs) (107) in the link box to form three loops R₁-Y₂-B₃ (loop 1) (501), Y₁-B₂-R₃ (loop 2) (502), and B₁-R₂-Y₃ (loop 3) (503), V_{R}, V_{Y}, and V_{B} are the three-phase source voltages (101), and RL_{R}, RL_{Y}, and RL_{B} are loads (102) of each phase. The metallic sheath of each phase is grounded at the grounding box through grounding resistances (RG₁, RG₂, RG₁′, RG₂′, RG₁″ and RG₂″) (103).

### BRIEF DESCRIPTION OF THE DRAWINGS

The foregoing summary, as well as the following detailed description of embodiments, is better understood when read in conjunction with the appended drawings. For the purpose of illustrating the disclosure, there is shown in the present document example constructions of the disclosure, however, the disclosure is not limited to the specific methods and device disclosed in the document and the drawing. The detailed description is described with reference to the following accompanying figures.

FIG. 1 illustrates a schematic diagram of a trefoil laying cable configuration, in accordance with an embodiment of the present subject matter.

FIG. 2 illustrates a schematic diagram of a major section in a CB cable, in accordance with an embodiment of the present subject matter.

FIG. 3 illustrates schematic diagram of a single point bonding at the beginning.

FIG. 4 illustrates schematic diagram of a single point bonding at the middle.

FIG. 5 illustrates schematic diagram of a two point bonding.

FIG. 6 illustrates a circuit model (500) of a major section of CB cable, in accordance with an embodiment of the present subject matter.

FIG. 7 illustrates a schematic diagram of loop 1 (R₁-Y₂-B₃) in a major section, in accordance with an embodiment of the present subject matter.

FIG. 8 illustrates an equivalent circuit for inductive current in loop 1, in accordance with an embodiment of the present subject matter.

FIG. 9 illustrates an equivalent circuit for capacitive current in loop 1, in accordance with an embodiment of the present subject matter.

FIG. 10 illustrates inductive circuit model for a single point bonding at the beginning.

FIG. 11 illustrates capacitive circuit model for a single point bonding at the beginning.

FIG. 12 illustrates inductive circuit model for a single point bonding at the middle.

FIG. 13 illustrates capacitive circuit model for a single point bonding at the middle.

FIG. 14 illustrates schematic diagram of three simultaneous major sections in a cross bonded cable.

FIG. 15 illustrates schematic diagram of three simultaneous sections in a two point bonded cable.

FIG. 16a illustrates a schematic diagram for the ground-to-sheath fault in loop 1, in accordance with an embodiment of the present subject matter.

FIG. 16b illustrates a graphical representation of grounding resistance currents for faults at different locations, in accordance with an embodiment of the present subject matter.

FIG. 17 illustrates grounding resistance currents for fault at different locations for a single point bonding at the beginning.

FIG. 18(a) illustrates grounding resistance currents for fault at different locations for a single point bonding at the middle.

FIG. 18(b) illustrates Phase difference between sheath and conductor current for fault for fault at different locations for a single point bonding at the middle.

FIG. 19 illustrates grounding resistance currents for fault at different locations for a two point bonding.

FIG. 20(a) illustrates an equivalent circuit for an SG fault showing inductive current in the first minor section, in accordance with an embodiment of the present subject matter. capacitive current

FIG. 20(b) illustrates an equivalent circuit for an SG fault showing capacitive current in the first minor section, in accordance with an embodiment of the present subject matter.

FIG. 21(a) illustrates an equivalent circuit for an SG fault showing inductive current in the second minor section, in accordance with an embodiment of the present subject matter.

FIG. 21(b) illustrates an equivalent circuit for an SG fault showing capacitive current in the second minor section, in accordance with an embodiment of the present subject matter.

FIG. 22(a) illustrates an equivalent circuit for an SG fault showing inductive current in the third minor section, in accordance with an embodiment of the present subject matter.

FIG. 22(b) illustrates an equivalent circuit for an SG fault showing capacitive current in the third minor section, in accordance with an embodiment of the present subject matter.

FIG. 23(a) illustrates an equivalent circuit for an SG fault showing inductive current, for a single point bonding at the beginning.

FIG. 23(b) illustrates an equivalent circuit for an SG fault showing capacitive current, for a single point bonding at the beginning.

FIG. 24(a) illustrates an equivalent circuit for an SG fault showing inductive current, for a single point bonding at the middle.

FIG. 24(b) illustrates an equivalent circuit for an SG fault showing capacitive current, for a single point bonding at the middle.

FIG. 25 illustrates a flowchart of a method (1200) of obtaining the SG fault in a CB (111) power cable, in accordance with an embodiment of the present subject matter.

FIG. 26 illustrates a flowchart of a method (1300) of obtaining the SG fault in a non CB power cable, in accordance with an embodiment of the present subject matter.

FIG. 27 illustrates an experimental setup to estimate the location of the ground to sheath fault, in accordance with an embodiment of the present subject matter.

FIG. 28 illustrates measured faults current at RG₁ and RG₂ for different practical case study (a) Case I, (b) Case II, (c) Case III, (d) Case IV (c) Case V (f) Case VI (g) Case VII, in accordance with an embodiment of the present subject matter.

FIG. 29 illustrates measured faults current at RG₁ and RG₂ for different simulated case study (a) Case I, (b) Case II, (c) Case III, (d) Case IV (c) Case V (f) Case VI (g) Case VII, in accordance with an embodiment of the present subject matter.

FIG. 30 illustrates measured faults current at RG₁ for single point bonding at the beginning for practical case studies for different practical case study (a) Case I, (c) Case II, in accordance with an embodiment of the present subject matter.

FIG. 31 (a) illustrates measured faults current at RG₁ (b) illustrates phase difference of measured sheath current with conductor current for single point bonding at the middle for practical case Case I, in accordance with an embodiment of the present subject matter.

FIG. 32 (a) illustrates measured faults current at RG₁ (b) illustrates phase difference of measured sheath current with conductor current for single point bonding at the middle for practical case Case II, in accordance with an embodiment of the present subject matter.

FIG. 33 (a) illustrates measured faults current at RG₁ (b) illustrates phase difference of measured sheath current with conductor current for single point bonding at the middle for practical case Case III, in accordance with an embodiment of the present subject matter.

FIG. 34 illustrates measured faults current at RG₁ two points bonding for different practical case study (a) Case I, (b) Case II, (c) Case III, (d) Case IV (e) Case V, in accordance with an embodiment of the present subject matter.

FIG. 35 illustrates simulated faults current at RG₁ for single point bonding at the beginning for simulated case studies for different practical case study (a) Case I, (c) Case II, in accordance with an embodiment of the present subject matter.

FIG. 36 (a) illustrates simulated faults current at RG₁, in accordance with an embodiment of the present subject matter.

FIG. 36 (b) illustrates phase difference of simulated sheath current with conductor current for single point bonding at the middle for simulated Case I, in accordance with an embodiment of the present subject matter.

FIG. 37 (a) illustrates simulated faults current at RG₁, in accordance with an embodiment of the present subject matter.

FIG. 37 (b) illustrates phase difference of simulated sheath current with conductor current for single point bonding at the middle for simulated Case II, in accordance with an embodiment of the present subject matter.

FIG. 38 (a) illustrates simulated faults current at RG₁, in accordance with an embodiment of the present subject matter.

FIG. 38 (b) illustrates phase difference of simulated sheath current with conductor current for single point bonding at the middle for simulated Case III, in accordance with an embodiment of the present subject matter.

FIG. 39 illustrates simulated faults current at RG₁ two points bonding for different simulated case study (a) Case I, (b) Case II, (c) Case III, (d) Case IV (e) Case V, in accordance with an embodiment of the present subject matter

### DETAILED DESCRIPTION

Some embodiments of the present disclosure, illustrating all its features, will now be discussed in detail. The words “comprising”, “receiving”, “determining”, “generating” and other forms thereof, are intended to be equivalent in meaning and be open-ended in that an item or items following any one of these words is not meant to be an exhaustive listing of such item or items, or meant to be limited to only the listed item or items. It must also be noted that as used herein and in the appended claims, the singular forms “a”, “an” and “the” include plural references unless the context clearly dictates otherwise. Although any systems and methods similar or equivalent to those described herein can be used in the practice or testing of embodiments of the present disclosure, the exemplary method (1200) of locating a sheath to ground faults in cross-bonded (CB) cables (111), and the the exemplary method (1300) of locating a sheath to ground faults in non cross-bonded cables, are now described. The disclosed embodiments of the method (1200) of locating the fault in the CB power cable and (1300) of locating the fault in the non CB power cable are merely exemplary of the disclosure, which may be embodied in various forms.

Various modifications to the embodiment will be readily apparent to those skilled in the art and the generic principles herein may be applied to other embodiments. However, one of ordinary skill in the art will readily recognize that the present disclosure for method (1200) of locating a sheath to ground faults in cross-bonded (CB) cables (111), and method (1300) of locating a sheath to ground faults in non cross-bonded cable as in single point grounded in the beginning or at the end (200), single point grounded at the middle (300), and two point grounded (400) is not intended to be limited to the embodiments illustrated, but is to be accorded the widest scope consistent with the principles and features described herein.

In an embodiment, the system (100) addresses or locates the sheath to ground fault in any arbitrary location in a CB high-voltage cable (111) during online conditions. This was performed only by measuring the current at the grounding resistance (103) in a straight-through joint by which the location of an SG fault at any arbitrary location can be identified with pinpoint accuracy. Analytical formulae were proposed, which can establish a relationship between the conductor current and phase voltage with the sheath current along with a circuit model (500) for a CB cable (111). Whenever there is an SG fault, the circuit will distort causing a change in the circulating current. The measured circulating current from the grounding resistance (103) is different from that of the healthy one. Therefore, an analytical range of both the grounding current is obtained, to estimate the minor section having the fault. After that empirical formulae were proposed to pinpoint the location of the SG from any of the measured grounding currents.

The system (100) further discloses one major section, this section was further divided into three subsections, where the detailed theory about the proposed circuit model (500) of the CB cable (111) along with the healthy case grounding current is described in the first subsection. In the second subsection, the formulae to detect the presence of SG fault along with the formulae to identify its location is presented. In the third subsection, the details about the practical and simulated results were presented.

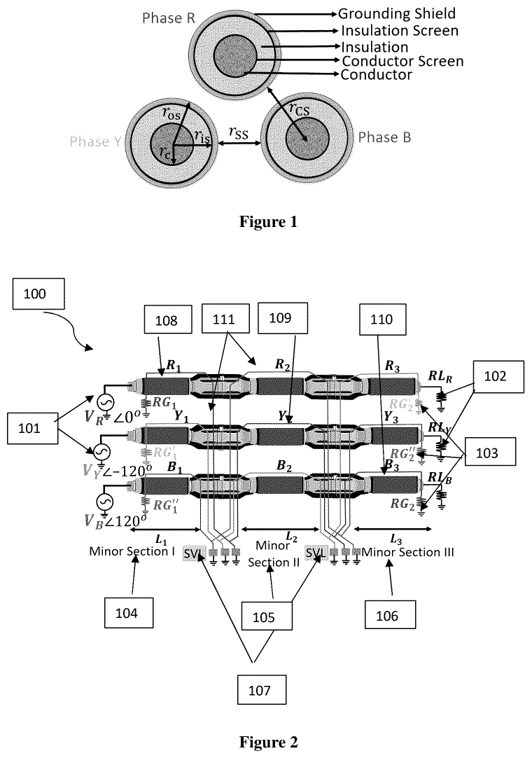

In accordance with an embodiment, referring to FIG. 1, FIG. 1 illustrates a high voltage cross-bonded (CB) power cable (111) having 3 phases R (108), Y (109), and B (110). The transposition of the metallic sheath is usually preferred over conductor transposition in a high-voltage CB power cable (111) as shown in equation no (2). For a metallic sheath transposition, the laying of cable is configured in a trefoil formation as shown in FIG. 1.

Now referring to FIG. 2 illustrates the system (100) comprising a schematic diagram of a major section of CB cable (111). Where, L₁, L₂, and L₃ are the lengths of the three minor sections named Rⱼ, Yⱼ, and Bⱼ (j=1, 2, and 3 representing each minor section), interconnected with sheath voltage limiters SVLs (107) in the link box to form three loops: R₁-Y₂-B₃ (loop 1) (501), Y₁-B₂-R₃ (loop 2) (502), and B₁-R₂-Y₃ (loop 3) (503). V_{R}, V_{Y}, and V_{B} are the three-source voltages (101) and RL_{R}, RL_{Y}, and RL_{B} are the loads (102) of each phase. The metallic sheath of each phase is grounded at the grounding box through grounding resistances (RG₁, RG₂, RG₁′, RG₂′, RG₁″ and RG₂″) (103).

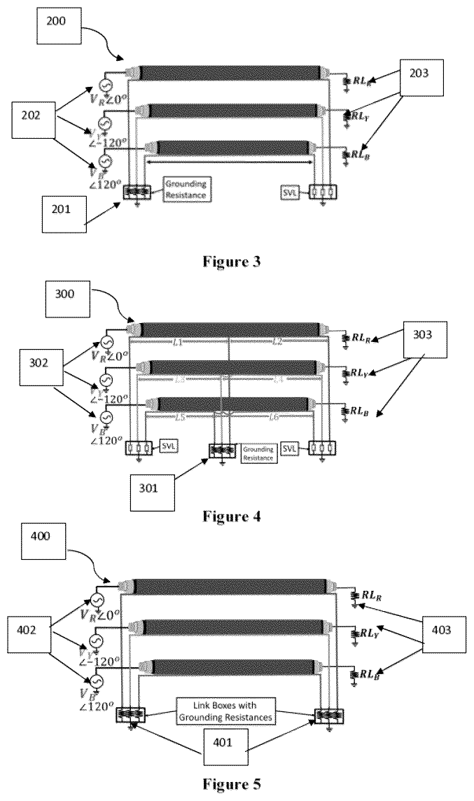

Now referring to FIG. 3 illustrates the system (200) comprising a schematic diagram of a major section of a single point grounded at the beginning (201) cable. Where, V_{R}, V_{Y}, and V_{B} are the three-source voltages (202) and RL_{R}, RL_{Y}, and RL_{B} are the loads (203) of each phase. The metallic sheath of each phase is grounded at the grounding box through grounding resistances.

Now referring to FIG. 4 illustrates the system (300) comprising a schematic diagram of a major section of a single point grounded at the middle (301) cable. Where, L₁, L₃, and L₅ are the length of the three phase cable from the source to the ground and L₂, L₄, and L₆ are the length of the three phase cable from the ground to load. V_{R}, V_{Y}, and V_{B} are the three-source voltages (302) and RL_{R}, RL_{Y}, and RL_{B} are the loads (303) of each phase. The metallic sheath of each phase is grounded at the grounding box through grounding resistances.

Now referring to FIG. 5 illustrates the system (400) comprising a schematic diagram of a major section of a two point grounded at the middle (401) cable. Where, V_{R}, V_{Y}, and V_{B} are the three-source voltages (402) and RL_{R}, RL_{Y}, and RL_{B} are the loads (403) of each phase. The metallic sheath of each phase is grounded at the grounding box through grounding resistances.

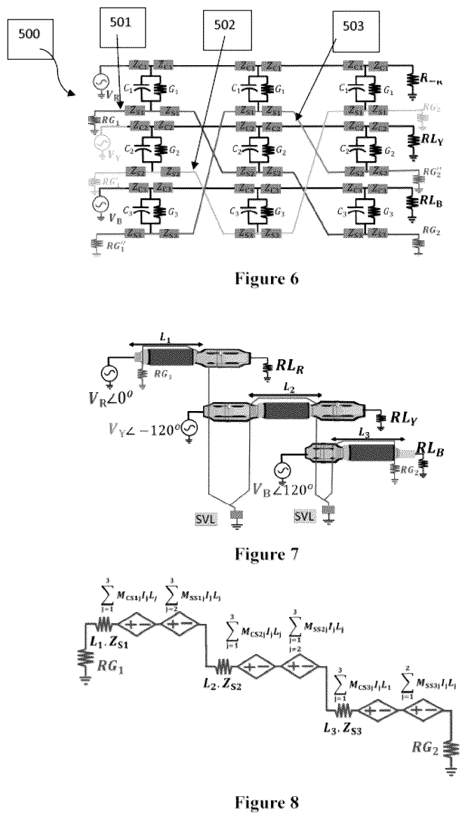

Now referring to FIG. 6 illustrates a circuit model (500) of a major section of CB (111) cable. Where, Z_{ci}, Zₛᵢ Cᵢ, and Gᵢ, are the conductor impedance, sheath impedance, insulation capacitance, and conductance respectively (i=1, 2, 3 for three different phases). By assuming that the condition of the insulation of the cable will remain unchanged throughout the length of the cable, during measurement. The current in the metallic sheath is mainly composed of leakage current, capacitive current, and inductive current. Since the condition of the insulation is considered to be constant and healthy, the value of leakage current would be in the range of <10⁻¹¹ A (depending on the operating voltage) and, therefore can be neglected while calculating the net sheath current (the effect of the other two currents would be in the range of a few amperes). Since the capacitive and inductive current are considered while calculating the net sheath current, the capacitance (C) and impedance of the metallic sheath (Zₛ) are only considered and per unit capacitance and impedance of the sheath in each minor section can be obtained analytically as:

$${C}_{i} = \frac{55.63 \times 1 {0}^{- 12} \times {ε}_{r}}{ln ln ( \frac{{r}_{i s}}{{r}_{c}} )} F / m \qquad ( 1 )$$

$${Z}_{S i} = {R}_{s i} + j ω ( {L}_{s i} + {M}_{C S i} + {M}_{S S i} ) Ω / m \qquad ( 2 )$$

In equation (1), i=1, 2, 3 representing three phases, εᵣ, is the relative permittivity of the insulating material and r_{c} is the conductor radius. while in (2) Rₛ is the resistance of the sheath, and Lₛ is the self-inductance of the sheath caused by the circulating current, M_{CS} and M_{SS} are the mutual inductance between the current-carrying conductor in each phase to a particular sheath and mutual inductance between other phase sheaths to the particular sheath. The analytical formula to obtain each of the above-mentioned terms for a trefoil formation of the cable is [16]:

$${R}_{s} = \frac{{k}_{r} ( 1 + {k}_{t} ( T - 20 ) )}{π ( {( {r}_{os} )}^{2} - {( {r}_{i s} )}^{2} )} Ω / m \qquad ( 3 )$$

$${L}_{s} = 2 \times 1 {0}^{- 7} ln ln ( \frac{2}{{r}_{o s} + {r}_{i s}} ) H / m$$

$${M}_{cs} = 2 \times 1 {0}^{- 7} ln ln ( \frac{\sqrt[3]{2}}{{r}_{c s}} ) H / m \qquad ( 4 )$$

$${M}_{s s} = 2 \times 1 {0}^{- 7} ln ln ( \frac{\sqrt[3]{2}}{{r}_{ss}} ) H / m$$

In the above formulae kᵣ, kₜ, and T are the metal sheath resistivity, temperature, and ambient temperature respectively. rₒₛ and rᵢₛ are the inner and outer radius of the metallic sheath, and r_{cs} and rₛₛ are the average distance between the conductor of one phase to the sheath of the calculating phase and the sheath of phase to the sheath of the calculating phase respectively.

Referring now to FIG. 7 illustrates a schematic diagram of loop 1 (R₁-Y₂-B₃) (501) in a major section. L₁, L₂, and L₃ are the lengths of the three minor sections named Rⱼ, Yⱼ, and Bⱼ (j=1, 2, and 3 representing each minor section), interconnected with SVLs (107) in the link box. Loop 1 (R₁-Y₂-B₃) (501) receives V_{R} receives a phase voltage at 0 degrees, V_{Y} receives a phase voltage at −120 degrees, and V_{B} receives the phase voltage at 120 degree, and RL_{R}, RL_{Y}, and RL_{B} are the loads (102) of each phase which are grounded.

Now referring to FIG. 8, FIG. 8 illustrates an equivalent circuit for inductive current in loop 1 (501). In each phase, the current in the conductor produces magnetic flux. This magnetic flux links the metallic sheath and produces a pseudo voltage due to Maxwell laws of electromagnetism, and due to the presence of a closed surface in the metallic sheath (grounded at both ends of a major section), an inductive circulating current will flow in the sheath. In each minor section, along with the current in the conductor of the particular phase, the current of the different phases of the conductor and metallic sheath will also impact the magnetizing current of a particular sheath. Since in a particular phase, the current is produced due to the pseudo voltage source which is dependent on the current in the conductor and sheath of other phases, this is represented as a voltage-controlled current source.

In FIG. 8, M_{csij}, FIG. 8 cs represents mutual inductance between the conductor of the different phases to the measuring sheath, and in Mₛₛᵢⱼ, ss represents mutual inductance between the different phase sheath to the measuring sheath, i represents the particular sheath where the measurements/calculation is carried out and j represents corresponding to other phases mutual inductance for both the cases. Since a closed path is formed between two grounds RG₁ and RG₂, the inductive current in the metallic sheath is obtained using Krichoffs voltage law (KVL) and is represented as:

$${I}_{m} = \frac{( {M}_{e q} {I}_{e q} {L}_{e q} )}{( R {G}_{2} + {Z}_{S} {L}_{e q} + R {G}_{1} )} \qquad ( 5 )$$

$$Where ,$$

$${Z}_{S} {L}_{e q} = {Z}_{S 1} {L}_{1} + {Z}_{S 2} {L}_{2} + {Z}_{S 3} {L}_{3} , and$$

$${M}_{e q} {I}_{e q} {L}_{e q} = ( {\sum }_{j = 1}^{3} {{M}_{CS 1}}_{j} {I}_{j} {L}_{j} + {M}_{C S 2 j} {I}_{j} {L}_{j} + {M}_{C S 3 j} {I}_{j} {L}_{j} + {\sum }_{j = 2}^{3} {M}_{SS 1 j} {L}_{j} {I}_{j} ) + ( {\sum }_{j = 1 j \neq 2}^{3} {M}_{S S 2 j} {L}_{j} {I}_{j} + {\sum }_{j = 1}^{2} {M}_{S S 3 j} {L}_{j} {I}_{j} ) \qquad ( 6 )$$

In the equations (5) and (6), the value of each term can be analytically obtained using equations no (2) and (4).

Now referring to FIG. 9, FIG. 9 illustrates an equivalent circuit for capacitive current in loop 1 (501). The phase voltage in each minor section is responsible for the capacitive current in the metallic sheath. The analytical relation between the per-phase voltage (V) and per-unit capacitive current (I_{C}) in the metallic sheath is I_{ci}=jωCᵢVᵢ, here i=1, 2, and 3, representing three different phases. Since the capacitive current is dependent on per-phase voltage, therefore for loop 1 (501), it is represented by the voltage control current source. The capacitive current flows out from the middle of each section as shown in FIG. 9.

The capacitive current through grounding resistance RG₁ and RG₂ (103) as I_{CRG1} and I_{CRG2} is obtained using Krichoff's current law (KCL) and is represented as:

$${I}_{CRG 1} = \frac{( {I}_{C 1} ( {Z}_{s 3} {L}_{3} + {Z}_{s 2} {L}_{2} + \frac{{Z}_{s 1} {L}_{1}}{2} + R {G}_{2} ) + {I}_{C 2} ( {Z}_{s 3} {L}_{3} + \frac{{Z}_{s 2} {L}_{2}}{2} + R {G}_{2} ) + {I}_{C2} ( \frac{{Z}_{s 3} {L}_{3}}{2} + R {G}_{2} ) )}{( R {G}_{2} + {Z}_{s} {L}_{e q} + R {G}_{1} )} \qquad ( 7 )$$

$${I}_{C R G 2} = \frac{( {I}_{C 1} ( \frac{{Z}_{s 2} {L}_{2}}{2} + {RG}_{1} ) + {I}_{C 2} ( {{Z}_{s}}_{1} {L}_{1} + \frac{{Z}_{s 2} {L}_{2}}{2} + R {G}_{1} ) + {I}_{C 3} ( {Z}_{s 1} {L}_{1} + {Z}_{s 2} {L}_{2} + \frac{{{Z}_{s}}_{3} {L}_{3}}{2} + R {G}_{1} ) )}{( R {G}_{2} + {Z}_{s} {L}_{e q} + R {G}_{1} )} \qquad ( 8 )$$

In equation no. (7) and (8), the value of each term can be analytically obtained using equations no (2) and (4). Therefore the total circulating current (I_{cc}) in healthy conditions flowing through the grounding resistances RG₁ and RG₂ (103) demonstrated as I_{ccRG1} and I_{ccRG2} respectively can be analytically obtained as:

$${I}_{c c R G 1} = {I}_{m} + {I}_{C R G 1} , {I}_{c c R G 2} = {I}_{m} + {I}_{C R G 2} \qquad ( 9 )$$

Equation no (9), will only match with practical measurements when the load is connected with the source with a single CB (111). However, whenever there is simultaneous CB (111) as shown in FIG. 7, then the measuring grounding current (I_{msrd1} and I_{msrd2}) of the major section II will be the simultaneous circulating current (I_{ccRG1S} and I_{ccRG25} from the simultaneous previous and succeeding major sections respectively) subtracted from the actual circulating current in the major section II. Therefore, from FIG. 14, the measuring grounding current of RG₁ and RG₂ in the major section II would be:

$${I}_{msrd 1} = {I}_{c c R G 1} - {I}_{ccRG 1 S} , {I}_{m s r d 2} = {I}_{c c R G 2} - {I}_{c c R G 2 S} \qquad ( 10 )$$

I_{cCRG1S} and I_{ccRG2S} are the analytically obtained simultaneous circulating current flowing in the major sections I and III, and can be obtained similarly to I_{ccRG1} and I_{ccRG2} using equation no (9).

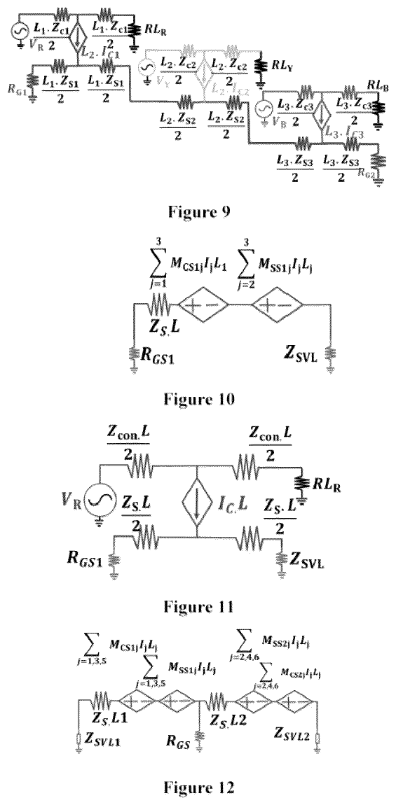

In FIG. 10, FIG. 10 represents mutual inductance between the conductor of the different phases to the measuring sheath for a single point grounded at the beginning, and in Mₛₛᵢⱼ, ss represents mutual inductance between the different phase sheath to the measuring sheath, i represents the particular sheath where the measurements/calculation is carried out and j represents corresponding to other phases mutual inductance for both the cases. Since a closed path is formed between grounds RG₁ and SVL, the inductive current in the metallic sheath is obtained using Krichoffs voltage law (KVL) and is represented as:

$${I}_{i n duct} = \frac{( {M}_{e q} {I}_{e q} {L}_{e q} )}{( {Z}_{S V L} + {Z}_{S} {L}_{e q} + R G 1 )} \qquad ( 11 )$$

$$Where ,$$

$${Z}_{S} {L}_{e q} = {Z}_{S1} {L}_{1} + {Z}_{S 2} {L}_{2} + {Z}_{S 3} {L}_{3} , and$$

$${M}_{e q} {I}_{e q} {L}_{e q} = {\sum }_{j = I}^{3} {M}_{CS 1 j} {I}_{j} {L}_{j} + {\sum }_{j = 2}^{3} {M}_{SS 1 j} {L}_{j} {I}_{j} \qquad ( 12 )$$

Now referring to FIG. 11, FIG. 11 illustrates an equivalent circuit for capacitive current in loop 1. The phase voltage in each minor section is responsible for the capacitive current in the metallic sheath. Since the capacitive current is dependent on per-phase voltage, it is represented by the voltage control current source. The capacitive current flows out from the middle of each section as shown in FIG. 11.

$${I}_{C R G} = \frac{( {I}_{C} ( \frac{{Z}_{S} L}{2} + {Z}_{s v l} ) )}{( {Z}_{SVL} + {Z}_{S} L + RG 1} \qquad ( 13 )$$

The analytical form of measured current (I_{M1}) can be analytically obtained as:

$${I}_{M 1} = {I}_{induct} + {I}_{C R G} \qquad ( 14 )$$

In FIG. 12, FIG. 12 represents mutual inductance between the conductor of the different phases to the measuring sheath for a single point grounded at the middle, and in Mₛₛᵢⱼ, ss represents mutual inductance between the different phase sheath to the measuring sheath, i represents the particular sheath where the measurements/calculation is carried out and j represents corresponding to other phases mutual inductance for both the cases. Since a closed path is formed between grounds RG₁ and SVL and RG₂ and SVL, the two inductive current in the metallic sheath is obtained using Krichoffs voltage law (KVL) and is represented as:

$${I}_{i n d u c t 1} = \frac{{\sum }_{j = 1 , 3 , 5} {M}_{C S 1 j} {I}_{j} {L}_{j} + {\sum }_{j = 1 , 3 , 5} {M}_{SS1j} {I}_{j} {L}_{j}}{{Z}_{S} \cdot L 1 + {Z}_{S V L 1} + R G 1} \qquad ( 15 )$$

$${I}_{induct 2} = - \frac{{\sum }_{j = 2 , 4 , 6} {M}_{C S 2 j} {I}_{j} {L}_{j} + {\sum }_{j = 2 , 4 , 6} {M}_{S S 2 j} {I}_{j} {L}_{j}}{{Z}_{S} \cdot L 2 + {Z}_{S V L 2} + R G 1} \qquad ( 16 )$$

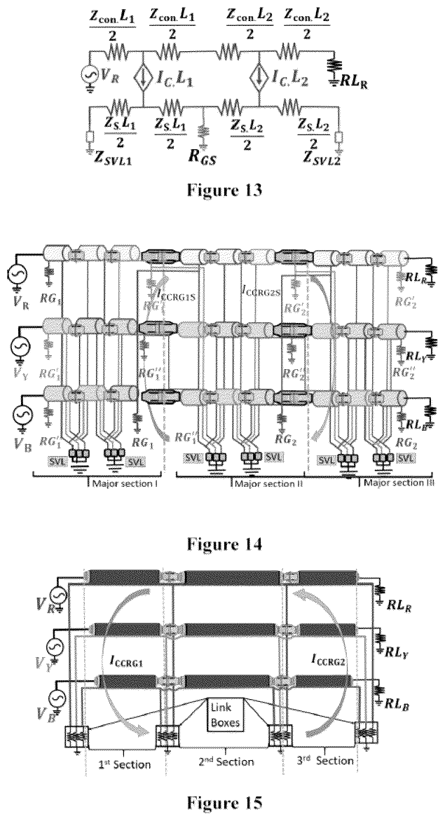

Now referring to FIG. 13, FIG. 13 illustrates an equivalent circuit for capacitive current in loop 1. The phase voltage in each minor section is responsible for the capacitive current in the metallic sheath. Since the capacitive current is dependent on per-phase voltage, it is represented by the voltage control current source. The capacitive current flows out from the middle of each section as shown in FIG. 13.

$${l}_{CRG 1} = \frac{( {I}_{C} ( ( \frac{{Z}_{s} L 1}{2} + {Z}_{svl 1} ) ( {Z}_{s} L 2 + {Z}_{svl 2} ) ) + {I}_{C} ( ( \frac{{Z}_{S} L 2}{2} + {Z}_{svl 2} ) ( {Z}_{s} L 1 + {Z}_{svl 1} ) ) )}{( ( {Z}_{s} L 2 + {z}_{SVL 2} ) ( {Z}_{s} L 1 + {Z}_{S V L 1} ) + RG 1 ( {Z}_{s} L 1 + {Z}_{S} L 2 + {Z}_{SVL 1} + {Z}_{S V L 2} ) )} \qquad ( 17 )$$

The analytical form of measured current (I_{M2}) can be analytically obtained as:

$${I}_{M 2} = {I}_{induct 1} + {I}_{induct 2} + {I}_{C R G 1} \qquad ( 18 )$$

Similar to the single-point bonding (bonding at the end or beginning), the inductive current (I_{induct3}) flowing through the grounding resistance RG₁ for a two point bonded cable can be analytically expressed as:

$${I}_{induct 3} = \frac{( {M}_{e q} {I}_{e q} {L}_{e q} )}{( R {G}_{2} + {Z}_{S} {L}_{e q} + R {G}_{1} )} \qquad ( 19 )$$

$$Here ,$$

$${M}_{e q} {I}_{e q} {L}_{e q} = {\sum }_{j = 1}^{3} {M}_{C S 1 j} {I}_{j} {L}_{j} + {\sum }_{j = 2}^{3} {M}_{S S 1 j} {L}_{j} {I}_{j}$$

Similar to the single-point bonding (bonding at the end or beginning), the capacitive current (I_{CRG2} and I_{CRG3}) flowing through the grounding resistance RG1 and RG2 for a two point bonded cable can be analytically expressed as:

$${I}_{C R G 2} = \frac{( {I}_{C} ( \frac{{Z}_{s} L}{2} + RG 2 ) )}{( R G 2 + {Z}_{s} L + R G 1 )} \qquad ( 20 )$$

$${I}_{C R G 3} = \frac{( {I}_{C} ( \frac{{Z}_{s} L}{2} + RG 1 ) )}{( R G 1 + {Z}_{s} L + R G 1 )} \qquad ( 21 )$$

The analytical form of measured current (I_{M3}) from RG1 and (I_{M4}) from RG2 can be analytically obtained as:

$${I}_{M 3} = {I}_{induct 3} + {I}_{CRG 2} \qquad ( 22 )$$

$${I}_{M 4} = {I}_{induct 3} + {I}_{CRG 3} \qquad ( 23 )$$

Now referring to FIG. 15, FIG. 15, whenever there is simultaneous cable section (major section I, II and III), then the measuring grounding current (I_{M3}′ and I_{M4}′) for a particular loop in the major section II will be the simultaneous circulating current (I_{cal1} and I_{cal2}) from the simultaneous previous and succeeding major sections respectively) subtracted from the actual circulating current in the major section II. Therefore, the measuring grounding current of RG1 and RG2 in the major section II would be

$${I}_{M 3}^{′} = {I}_{m 3} - {I}_{cal 1} , {I}_{M 3}^{I} = {I}_{m 4} - {I}_{cal 2} \qquad ( 24 )$$

I_{cal1} and I_{cal2} are the analytically obtained simultaneous circulating current flowing in the major sections I and III, and can be obtained similarly to I_{M3} and I_{M3} using (22) and (23).

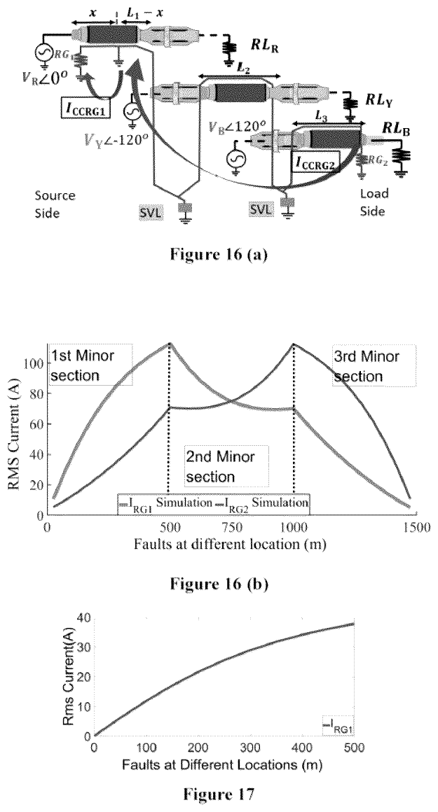

In an embodiment, FIG. 16a illustrates the schematic diagram for the ground-to-sheath fault in loop 1 (501). The metallic sheath of the high-voltage cable is made of aluminium (high-conductive material). Whenever any part of this metallic sheath comes in contact with the ground it causes changes in the inductive and capacitive of the cable which causes fault current to flow between the fault location and two grounding resistances RG₁ and RG₂ (103) as shown in FIG. 8a. Since the fault is happening on the metallic sheath (which is conducting), the resistance of the fault would be extremely less when compared with that with the metallic sheath, hence treated as shorted to ground.

In an embodiment, FIG. 16b illustrates the simulated results for faults at different locations in a major section of a CB (111) cable. The dimensions and electrical properties of the cable of the one major section considered between the source and the load is of total sheath length of 18 m, each subsection is of 6 m, and faults are created at 0 m, 3 m, 6 m, 9 m, 12 m, 15 m, and 18 m measuring from the source.

Whenever an SG fault occurs in a cable as shown in FIG. 16a, the magnitude of I_{ccRG1} and I_{ccRG2}. will be different when compared with that of a healthy case, since the circulating current is dependent on the mutual inductance and capacitance which directly depends on the length of the cable sheath as presented in Section II. Also as shown in FIG. 16b, the combined ranges for both I_{RG1} and I_{RG2} will be unique, for an SG fault at three different locations. This happens because, whenever an SG fault occurs at the first minor section, only the first phase conductor (supply) voltages and current will affect the I_{ccRG1}, however, both three phases conductor (supply) voltage (101) and current will affect the I_{ccRG2}, and vice versa will happen for fault at the third minor section. In the second minor section, the two-phase supply will impact both I_{ccRG1} and I_{ccRG2}. Therefore three unique sets of I_{ccRG1} and I_{ccRG2} will form three different minor sections. Therefore applying a KVL and KCL between both the grounding resistance (103) and sheath to the ground fault and using maximum and minimum values for the length of the minor section, a range of I_{RG1} and I_{RG2} values were obtained analytically. The measured ground current of both the resistance was compared with the analytically obtained range of values. If the measured value is not in the analytically obtained ranges then the cable does not have a SG fault. The equations are further solved to obtain the pinpoint locations of the SG fault. To facilitate the calculation, the distance from the source to the fault is considered to be x for the particular minor section, whereas from the fault location to the load (102) is considered to be Lᵢ-x, here i=1, 2, 3 representing the length of the minor sections as shown in FIG. 16a.

In an embodiment, FIG. 17 illustrates the simulated results of magnitude of sheath current in the grounding resistance for faults at different locations in a major section of single end bonded cable at the beginning. The dimensions and electrical properties of the cable of the one major section considered between the source and the load is of total sheath length of 500 m.

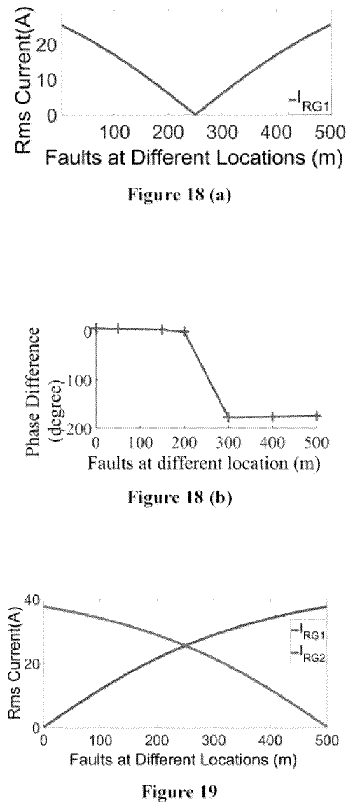

In an embodiment, FIGS. 18a and 18b illustrates the simulated results of magnitude of sheath current in the grounding resistance and phase difference for sheath and conductor current for faults at different locations in a major section of single end bonded cable at the middle. The dimensions and electrical properties of the cable of the one major section considered between the source and the load is of total sheath length of 500 m.

In an embodiment, FIG. 19 illustrates the simulated results of magnitude of sheath current in both the grounding resistance RG1 and RG2 for faults at different locations in a major section of single end bonded cable at the beginning. The dimensions and electrical properties of the cable of the one major section considered between the source and the load is of total sheath length of 500 m.

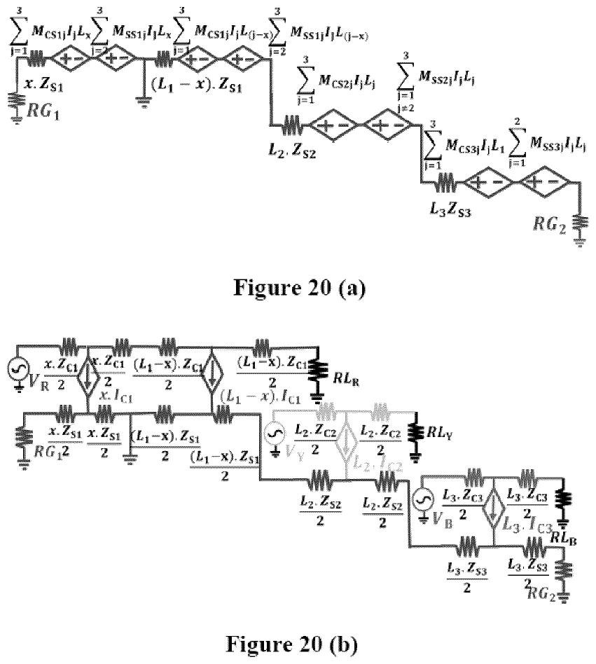

Now referring to FIGS. 20a and 20b illustrates an equivalent circuit for inductive and capacitive current respectively for a ground-to-sheath fault at the first minor section. Both circuits 20a and 20b are solved using KVL and KCL, as done for the healthy section (section II). To obtain the maximum and minimum value of I_{RG1} and I_{RG2} for an SG fault at the first minor section, the maximum and minimum value of x is considered (0≤x<L₁). The range of values of the ground currents for the sheath fault at the first minor section (104) is expressed as:

$${I}_{RG 1} = [ 0 , \frac{{I}_{C 1} {Z}_{S 1} {L}_{1} + 2 ( {\sum }_{j = 1}^{3} {M}_{CS 1} {I}_{j} {L}_{j} + {\sum }_{j = 2}^{3} {M}_{SS 1 j} {L}_{j} {I}_{j} )}{2 ( {Z}_{S 1} {L}_{1} + {RG}_{1} )} ) \qquad ( 25 )$$

$${I}_{R G 2} = [ \frac{( {M}_{eq} {L}_{eq} {I}_{eq} ) + {Z}^{′} {I}^{′}}{Z {L}_{eq} + {RG}_{2}} , \frac{( {M}_{2 , 3} {L}_{2 , 3} {I}_{2 , 3} ) + {Z}^{″} {I}^{″}}{{Z}_{S 2} {L}_{2} + {Z}_{S 3} {L}_{3} + {RG}_{2}} ) \qquad ( 26 )$$

$${Z}^{′} {I}^{′} = \frac{{I}_{C 1} {Z}_{S 1} {L}_{1}}{2} + {I}_{C 2} ( {Z}_{S 1} {L}_{1} + \frac{{Z}_{S 2} {L}_{2}}{2} ) + {I}_{C 3} ( {Z}_{S 1} {L}_{1} + {Z}_{S 2} {L}_{2} + \frac{{Z}_{S 3} {L}_{3}}{2} ) ,$$

$${M}_{2 , 3} {L}_{2 , 3} {I}_{2 , 3} = {\sum }_{i = 2 , j = 1}^{i = 3 , j = 3} {M}_{CSij} {I}_{j} {L}_{j} + {\sum }_{i = 2 , j = 1}^{i = 3 , j = 3} {M}_{SH 3 j} {I}_{j} {L}_{j} , and$$

$${Z}^{″} {I}^{″} = {I}_{C 2} ( \frac{{Z}_{2} {L}_{2}}{2} ) + {I}_{C 3} ( {Z}_{2} {L}_{2} + \frac{{Z}_{3} {L}_{3}}{2} )$$

The circuit illustrated in FIGS. 20a and 20b is further solved to obtain the location of x (location of sheath fault) for both I_{RG1} and I_{RG2} values. The location of ground to sheath fault a/c to I_{RG1}

$$x = \frac{{I}_{RG 1} {RG}_{1}}{{\sum }_{j = 1}^{3} {M}_{CS 1 j} {I}_{j} + {\sum }_{j = 2}^{3} {M}_{SS 1 j} {I}_{j} - {I}_{RG 1} {Z}_{S 1} + {I}_{C 1}} \qquad ( 27 )$$

The location of ground to sheath fault a/c to I_{RG2} (considering the positive value of x)

$$x = \frac{- {α}^{′} + \sqrt{{( {α}^{′} )}^{2} - 4 {I}_{C 1} {β}^{′}}}{{I}_{C 1}} \qquad ( 28 )$$

$${α}^{′} = {Z}_{S 1} {I}_{R G 2} - ( {I}_{C 1} {Z}_{1} + {I}_{C 2} {Z}_{2} + {I}_{C 3} {Z}_{3} ) - {\sum }_{j = 1}^{3} {M}_{CS 1 j} {I}_{j} + {\sum }_{j = 2}^{3} {M}_{S S 1 j} {I}_{j} ,$$

$$and$$

$${β}^{′} = {Z}^{′} {I}^{′} + {M}_{eq} {L}_{eq} {I}_{e q} - {I}_{R G 2} ( {RG}_{2} + {Z}_{S} {L}_{eq} )$$

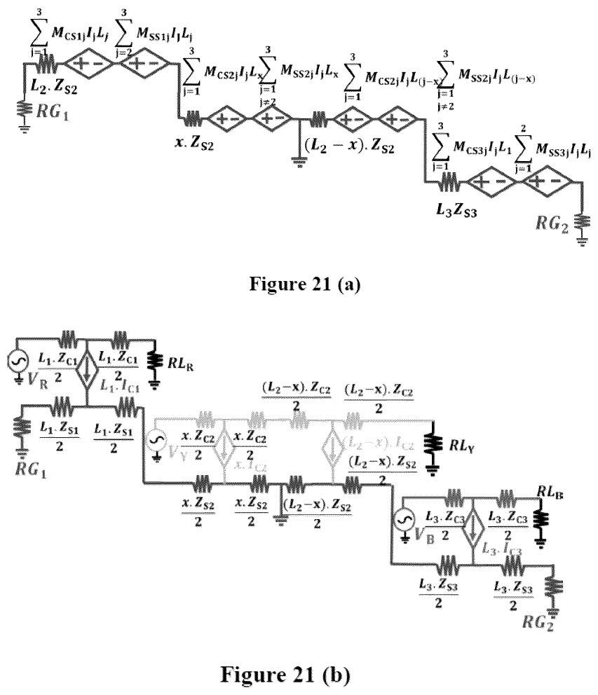

Now referring to FIGS. 21a and 21b illustrates an equivalent circuit for inductive and capacitive current for a ground-to-sheath fault at the second minor section. Both circuits 21a and 21b are solved using KVL and KCL. Maximum and minimum values of I_{RG1} and I_{RG2} are obtained by substituting the value of x as 0≤x<L₂. The range of values of the ground currents for the sheath fault at the second minor section (105) is expressed as:

$${I}_{R G 1} = [ \frac{{1}_{C 1} {Z}_{S 1} {L}_{1} + 2 ( {\sum }_{j = 1}^{3} {M}_{CS 1 j} {I}_{j} {L}_{j} + {\sum }_{j = 2}^{3} {M}_{S S 1 j} {L}_{j} {I}_{j} )}{2 ( {Z}_{S 1} {L}_{1} + {RG}_{1} )} , \frac{{M}_{1 , 2} {L}_{1 , 2} {I}_{1 , 2} + {Z}^{′″} {I}^{′″}}{{z}_{s 1} {L}_{1} + {Z}_{S 2} {L}_{2} + {RG}_{1}} ) \qquad ( 29 )$$

$${I}_{R G 2} = [ \frac{( {M}_{2 , 3} {L}_{2 , 3} {I}_{2 , 3} ) + {Z}^{″} {I}^{″}}{{Z}_{S 2} {L}_{2} + {Z}_{S 3} {L}_{3} + {RG}_{2}} , \frac{2 ( {\sum }_{j = 1}^{3} {M}_{CS 3 j} {I}_{j} {L}_{j} + {\sum }_{j = 1}^{2} {M}_{SS 3 j} {L}_{j} {I}_{j} ) + {I}_{C 3} {Z}_{S 3} {L}_{3}}{2 ( {Z}_{S 3} {L}_{3} + {RG}_{2} )} ) \qquad ( 30 )$$

$${Z}^{″′} {I}^{″′} = \frac{{I}_{C 1} {Z}_{1} {L}_{1}}{2} ,$$

$$and {M}_{1 , 2} {L}_{1 , 2} {I}_{1 , 2} = {\sum }_{i = 1 , j = 1}^{i = 2 , j = 3} {M}_{CS 1 j} {I}_{j} {L}_{j} + {\sum }_{i = 1 , j = 2 , i \neq j}^{j = 2 , j = 3} {M}_{SSij} {I}_{j} {L}_{j}$$

The circuit shown in FIGS. 21a and 21b is further solved to obtain the location of x for both I_{RG1} and I_{RG2} values. The location of ground to sheath fault a/c to I_{RG1} (considering the positive value of x).

$$x = \frac{- {α}^{″} + \sqrt{{( {α}^{″} )}^{2} - 4 \cdot {I}_{C 2} {β}^{″}}}{2 \cdot {I}_{C 2}} \qquad ( 31 )$$

The location of ground to sheath fault a/c to I_{RG2} considering the positive value of x).

$$x = \frac{- {α}^{″′} + \sqrt{{( {α}^{″′} )}^{2} - 4 \cdot {I}_{C 2} \cdot {β}^{″′}}}{2 \cdot {I}_{C 2}} \qquad ( 32 )$$

$${α}^{″} = {I}_{C 1} {Z}_{S 1} + {\sum }_{j = 1}^{3} {M}_{CS 2 j} {I}_{j} + {\sum }_{j = 1 , j \neq 2}^{3} {M}_{SS 2 j} {I}_{j} - {Z}_{S 2} {I}_{RG 1} ,$$

$${α}^{″′} = {Z}_{S 2} {I}_{R G 2} - ( {I}_{C 2} {Z}_{2} + {I}_{C 3} {Z}_{S 3} ) - {\sum }_{j = 1}^{3} {M}_{C S 2 j} {I}_{j} + {\sum }_{j = 1 j \neq 2}^{3} {M}_{SS 2 j} {I}_{j} ,$$

$${β}^{″} = {Z}^{″′} {I}^{″′} + {\sum }_{j = 1}^{3} {M}_{C S 1 j} {I}_{j} {L}_{j} + {\sum }_{j = 2}^{3} {M}_{S S 1 j} {L}_{j} {I}_{j} - {I}_{R G 1} \cdot ( {RG}_{1} + {Z}_{S 1} {L}_{1} ) ,$$

$$and$$

$${β}^{″′} = {Z}^{″′} {I}^{″′} + {M}_{2 , 3} {L}_{2 , 3} {I}_{2 , 3} - {I}_{R G 2} ( {RG}_{2} + {Z}_{S 2} {L}_{2} + {Z}_{S 3} {L}_{3} )$$

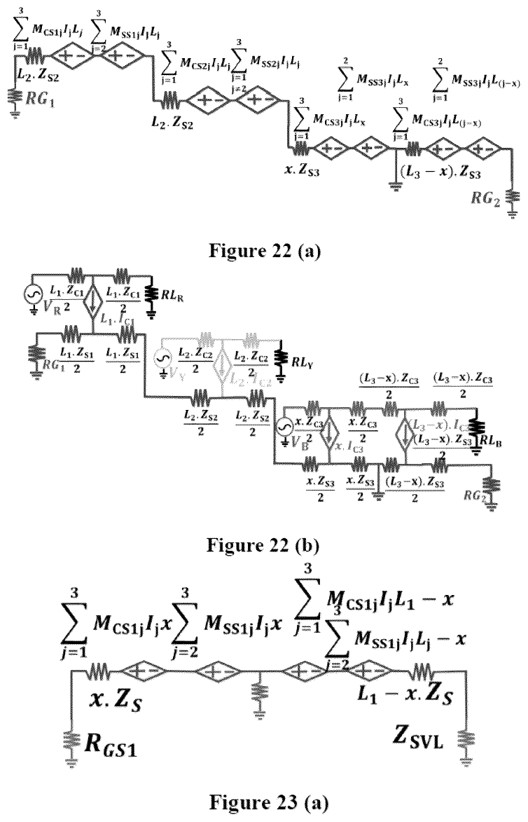

Now referring to FIGS. 22a and 22b illustrates an equivalent circuit for inductive and capacitive current respectively for a ground-to-sheath fault at the third minor section. Both circuits 22a and 22b are solved using KVL and KCL, as done for the healthy section. To obtain the maximum and minimum value of I_{RG1} and I_{RG2} for an SG fault at the third minor section, the maximum and minimum value of x is considered (0≤x<L₃). The range of values of the ground currents for the sheath fault at the first minor section (104) is expressed as:

$${I}_{R G 1} = [ \frac{( {M}_{1 , 2} {L}_{1 , 2} {1}_{1 , 2} ) + {Z}^{i v} {I}^{i v}}{{Z}_{S 1} {L}_{1} + {Z}_{S 2} {L}_{2} + R {G}_{1}} , \frac{\begin{matrix}{M}_{eq} {L}_{eq} {I}_{eq} + {I}_{C 1} ( \frac{{Z}_{S 1} {L}_{1}}{2} + {Z}_{S 2} {L}_{2} + {Z}_{S 3} {L}_{3} ) + \\ {I}_{C 2} ( \frac{{Z}_{S 2} {L}_{2}}{2} + {Z}_{S 3} {L}_{3} ) + {I}_{C 2} ( {Z}_{S 3} {L}_{3} )\end{matrix}}{( {Z}_{S} {L}_{eq} + {RG}_{1} )} ) \qquad ( 33 )$$

$${I}_{RG 2} = [ \frac{{I}_{C 3} {Z}_{S 3} {L}_{3} + 2 ( {\sum }_{j = 1}^{3} {M}_{CS 3 j} {I}_{j} {L}_{j} + {\sum }_{j = 1}^{2} {M}_{SS 3 j} {L}_{j} {I}_{j} )}{2 ( {Z}_{S 3} {L}_{3} + {RG}_{2} )} , 0 ) \qquad ( 34 )$$

$${Z}^{iv} {I}^{iv} = \frac{{I}_{C 1} {Z}_{S 1} {L}_{1}}{2} + {I}_{C 1} {Z}_{S 2} {L}_{2} + \frac{{I}_{C 2} {Z}_{S 2} {L}_{2}}{2} ,$$

The circuit illustrated in FIGS. 22a and 22b is further solved to obtain the location of x (location of sheath fault) for both I_{RG1} and I_{RG2} values. The location of ground to sheath fault a/c to I_{RG1}

$$x = \frac{- {α}^{iv} + \sqrt{{( {a}^{iv} )}^{2} - 4 {I}_{C 3} {β}^{iv}}}{{I}_{C 3}} \qquad ( 35 )$$

$${α}^{i v} = {I}_{C 1} {Z}_{S 1} + {I}_{C 2} {Z}_{S 2} + {\sum }_{j = 1}^{3} {M}_{C S 3 j} {I}_{j} + {\sum }_{j = 1}^{2} {M}_{SS 3 j} {I}_{j} + {Z}_{S 3} {I}_{R G 1} , and$$

$${β}^{i v} = {Z}^{i v} {I}^{i v} + {M}_{1 , 2} {L}_{1 , 2} {I}_{1 , 2} - {I}_{RG 1} ( {RG}_{1} + {Z}_{S 1} {L}_{1} + {Z}_{S 2} {L}_{2} )$$

The location of ground to sheath fault a/c to I_{RG2} (considering the positive value of x)

$$x = \frac{( {\sum }_{j = 1}^{3} {M}_{CS 1 j} {I}_{j} + {\sum }_{j = 2}^{3} {M}_{SS 1 j} {I}_{j} ) + {I}_{C 3} - 2 {I}_{R G 2} ( {RG}_{2} + {Z}_{S 3} {L}_{3} )}{{I}_{C 3} + 2 ( {\sum }_{j = 1}^{3} {M}_{CS 1 j} + {\sum }_{j = 2}^{3} {M}_{SS 1 j} {I}_{j} ) - 2 {I}_{R G 2} {Z}_{s 3}} \qquad ( 36 )$$

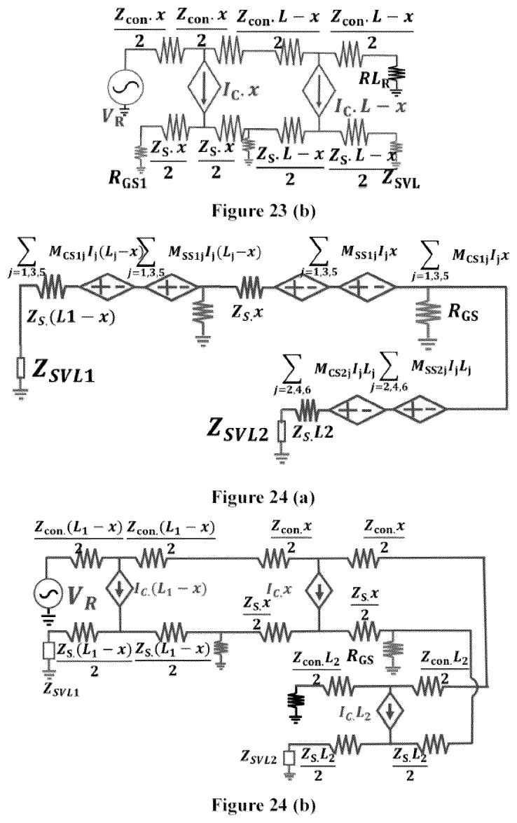

Now referring to FIGS. 23a and 23b illustrates an equivalent circuit for inductive and capacitive current respectively for a ground-to-sheath fault for a single end grounded cable at the beginning. Both circuits 23a and 23b are solved using KVL and KCL, as done for the healthy section. The location of ground to sheath fault a/c to RG1 is:

$$x = \frac{{I}_{M 1} RG 1}{{\sum }_{j = 1}^{3} {M}_{CS 1 j} {I}_{j} + {\sum }_{j = 2}^{3} {M}_{SS 1 j} {I}_{j} - {I}_{RG 1} {Z}_{s} + {I}_{C}} \qquad ( 37 )$$

Now referring to FIGS. 24a and 24b illustrates an equivalent circuit for inductive and capacitive current respectively for a ground-to-sheath fault for a single end grounded cable at the middle. Both circuits 24a and 24b are solved using KVL and KCL, as done for the healthy section. The location of ground to sheath fault between the source and the grounding resistance a/c to RG1 is:

$$x = \frac{- ρ + \sqrt{{( ρ )}^{2} - 4 \cdot γ \cdot δ}}{2 \cdot δ} \qquad ( 38 )$$

$$here ,$$

$$δ = \frac{{I}_{CRG 1} {Z}_{S} {Z}_{SVL 2}}{2} ,$$

$$ρ = {I}_{CRG 1} \cdot L 2 \cdot {Z}_{s} \cdot {Z}_{SVL 2} - {I}_{M 2.} {Z}_{s} \cdot {Z}_{SVL 2} + ( {\sum }_{j = 1}^{3} {M}_{CS 1 j} {I}_{j} {L}_{j} + {\sum }_{j = 2}^{3} {M}_{SS 1 j} {L}_{j} {I}_{j} ) {Z}_{SVL 2} ,$$

$$and$$

$$γ = {I}_{M 2} \cdot RG 1 \cdot {Z}_{SVL 2}$$

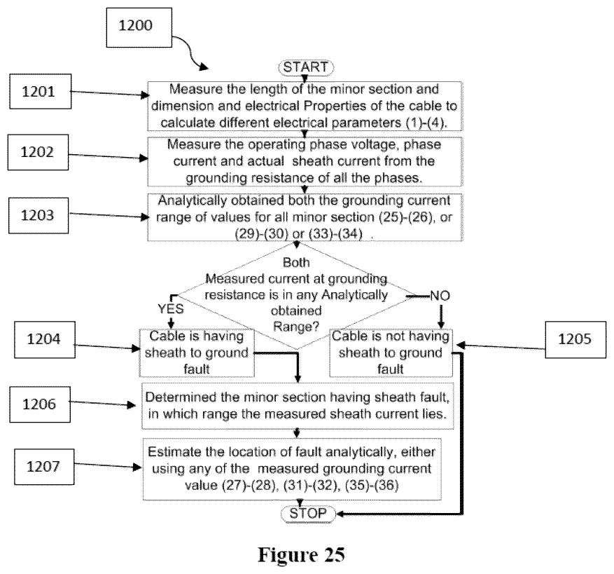

Now referring to FIGS. 25a and 25b illustrates an equivalent circuit for inductive and capacitive current respectively for a ground-to-sheath fault for a single end grounded cable at the middle. Both circuits 25a and 25b are solved using KVL and KCL, as done for the healthy section. The location of ground to sheath fault between the load and the grounding resistance a/c to RG1 is:

$$x = \frac{- {ρ}^{′} + \sqrt{{( {ρ}^{′} )}^{2} - 4 \cdot {γ}^{′} \cdot {δ}^{′}}}{2 \cdot {δ}^{′}} \qquad ( 39 )$$

$$here ,$$

$${δ}^{′} = \frac{{I}_{CRG 1} {Z}_{S} {Z}_{SVL 1}}{2} ,$$

$${ρ}^{′} = {I}_{CRG 1} \cdot L 1 \cdot {Z}_{s} \cdot {Z}_{SVL 1} - {I}_{M 2.} {Z}_{S} \cdot {Z}_{SVL 1} + ( {\sum }_{j = 1}^{3} {M}_{C S 1 j} {I}_{j} {L}_{j} + {\sum }_{j = 2}^{3} {M}_{SS 1 j} {L}_{j} {I}_{j} ) {Z}_{SVL 1} ,$$

$$and$$

$${γ}^{′} = {I}_{M 2} \cdot RG 1 \cdot {Z}_{SVL 1}$$

Similar to the single point grounded at the beginning, the location of ground to sheath fault a/c to RG1 is

$$x = \frac{{1}_{M 3} RG 1}{{\sum }_{j = 1}^{3} {M}_{CS 1 j} {I}_{j} + {\sum }_{j = 2}^{3} {M}_{S S 1 j} {I}_{j} - {I}_{R G 1} {Z}_{S} + {1}_{CRG 2}} \qquad ( 40 )$$

$$The location of ground to sheath fault a / c to RG 2 is$$

$$x = \frac{\begin{matrix}2 ( {\sum }_{j = 1}^{3} {M}_{C S 1 j} {I}_{j} {L}_{1} + {\sum }_{j = 1}^{2} {M}_{S S 1 j} {I}_{j} {L}_{j} ) + \\ {I}_{C R G 3} - 2 {I}_{M 4} ( R G 2 + {Z}_{S} L )\end{matrix}}{{I}_{CRG 3} + 2 ( {\sum }_{j = 1}^{3} {M}_{CS 1 j} {I}_{j} + {\sum }_{j = 2}^{3} {M}_{S S 1 j} {I}_{j} ) - 2 {I}_{M 4} {Z}_{S}} \qquad ( 41 )$$

In an embodiment, FIG. 25 illustrates a flowchart to obtain the sheath-to-ground (SG) fault in a cross-bonded (CB) (111) power cable.

At step 1201: Measure the length of the minor section, dimension, and electrical properties of the cross-bonded cable (CB) (111) to calculate different electrical parameters by using equation no (1) to (4).

At step 1202: Measuring the operating phase voltage, phase current, and actual sheath current by using equation no (10) from the grounding resistance (103) of all phases (R, Y, and B) (108) (109) (110) by utilizing current sensor.

At step 1203: Analytically obtain both the grounding current range of values for all minor sections by using equation no (25)-(26) or (29)-(30) or (33)-(34).

At step 1204: If both the measured current at grounding resistance (103) are in the range of analytically obtained value then the cable has having sheath-to-ground (SG) fault.

At step 1205: If both the measured current at grounding resistance (103) is out of the range of analytically obtained value then the cable does not have sheath-to-ground (SG) fault.

At step 1206: If the cable is having sheath-to-ground (SG) fault then determine which minor section has a sheath fault and also in which range the measured sheath current lies.

At step 1207: If the cable is having a sheath-to-ground (SG) fault then estimate the location of the fault analytically or either using any of the measured current values from equation no (27)-(28) or (31)-(32) or (35)-(36).

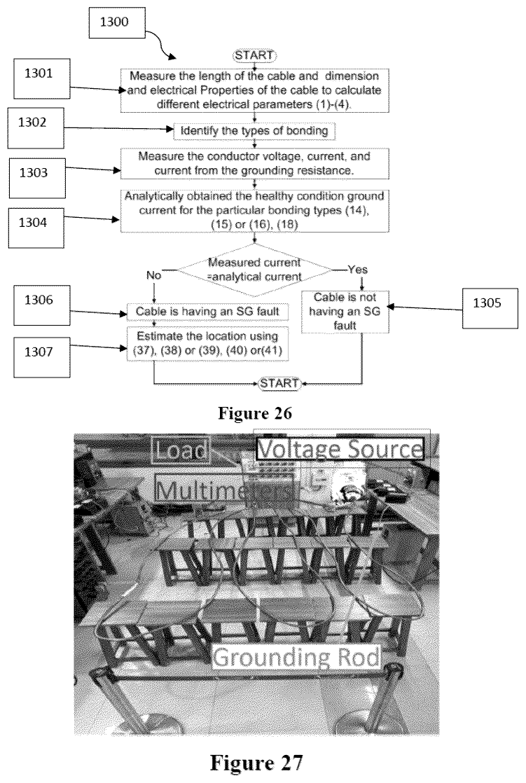

In an embodiment, FIG. 26 illustrates a flowchart to obtain the sheath-to-ground (SG) fault in a non cross-bonded power cable.

At step 1301: Measure the length of the minor section, dimension, and electrical properties of the non cross-bonded cable to calculate different electrical parameters by using equation no (1) to (4).

At step 1302: Identify the type of bonding (200), (300) or (400).

At step 1303: Measure the conductor voltage, current and current from the grounding resistance.

At step 1304: Analytically obtained the healthy condition grounding current from the grounding resistance for the particular type of bonding using (14), (15) or (16), (18).

At step 1305: If the measured current at grounding resistance (201), (301) and (401) matches with the analytically obtained value then the cable does not have a sheath-to-ground (SG) fault.

At step 1306: If the measured current at grounding resistance (201), (301) and (401) does not matches with the analytically obtained value then the cable have a sheath-to-ground (SG) fault.

At step 1307: If the cable is having a sheath-to-ground (SG) fault then estimate the location of the fault analytically from equation no (37), (38) and (39), (40) or (41)).

In an embodiment, FIG. 27 illustrate experimental case study that were considered to verify the analytical results. In the experimental study i.e., FIG. 27, HAVELLS three-core, XLPE insulated material was selected, with an inner conductor (Aluminium) area of 35 mm², outer grounded sheath diameter of 7.35 mm, the radius of the metallic sheath is 1 mm, and insulation relative permittivity of 2.3. The cable is laid in a trefoil formation with r_{cs} and rₛₛ as 8 cm, and 10 cm respectively. The value of RG₁ and RG₂ is kept at 0.2Ω respectively. The cable is supplied with a three-phase voltage of 440V (101) and a load current of 15 A (102). The ground current is measured using a FLUKE 17B Digital multi meter whose uncertainty in measurement is 1.5%. The cross cable (CB) (111) of the sheath is performed using metallic wire as shown in FIG. 13. To validate the analytical results seven different case studies are considered in this paper, in which the first four case studies are for the balance condition (unity power factor and same minor section length) and the next three are the unbalanced conditions (load of different power factor but voltage and current magnitude same or length of minor section or both). The faults are created using a grounding rod (103) of magnitude 3 mΩ. To cross-verify the analytical and experimental results, simulations are performed of the same dimension and fault location for all seven cases in MATLAB Simulink. These case studies are:
i.Case Study 1: One major section considered between the source and the load (102). Three 6 m long cables of the above-mentioned is CB (111) (total sheath length of 18 m), and faults are created at 0 m, 3 m, 6 m, 9 m, 12 m, 15 m, and 18 m measuring from the source.
ii.Case Study II: Three major sections are considered between the source and the load (102). Each major section is 6 m in length, and faults are created at 0 m, 3 m, 6 m, 9 m, 12 m, 15 m, and 18 m in the middle major section.
iii.Case Study III: Two major sections are considered between the source and the load (102). Each major section is 6 m in length, and faults are created at 0 m, 3 m, 6 m, 9 m, 12 m, 15 m, and 18 m at the first major section from the source end.
iv.Case Study IV: Similar to Case III, faults are at 0 m, 3 m, 6 m, 9 m, 12 m, 15 m, and 18 m at the second major section from the source end.
v.Case Study V: Similar to Case I, however, the power factor at three phases are 1, 0.9, and 0.85, while the magnitude of the current remains the same as a balanced case.
vi.Case Study VI: One major section considered between the source and the load (102) with unity power factor. Minor sections are 6 m, 5 m, and 4.5 m in length, and faults are created at 0 m, 3 m, 6 m, 8.5 m, 11 m, 13.5 m, and 15.5 m measuring from the source.
vii.Case Study VII: Similar to Case VI, however the power factor at three phases is 1, 0.9, and 0.85, while the magnitude of the current remains the same as a balanced case.

Apart from the experimental cable, which was of limited length, voltage, and current supply, the simulation was performed on MATLAB SIMULINK. The dimension, operating voltage, and current of the cable are kept similar to the second experimental case study. Just like the first experimental case study, seven different conditions are considered:
i. Case Study I: Unity power factor, only one major section between source and load (102), faults are created at 0 m, 250 m, 500 m, 750 m, 1000 m, 1250 m, and 1300 m.
ii. Case Study II: Unity power factor, two major sections between source and load (102), faults are created at the first major section from the load (102) at 0 m, 250 m, 500 m, 750 m, 1000 m, 1250 m, and 1300 m.
iii. Case Study III: Unity power factor, two major sections between source and load (102), faults are created at the first major section from the load (102) at 0 m, 250 m, 500 m, 750 m, 1000 m, 1250 m, and 1300 m.
iv. Case Study IV: Unity power factor, two major sections between source and load (102), faults are created at the second major section from the load (102) at 0 m, 250 m, 500 m, 750 m, 1000 m, 1250 m, and 1300 m.
v. Case Study V: Similar to Case I, however, the power factor at three phases are: 1, 0.9, and 0.85, while the magnitude of the current remains the same as a balanced case.
vi. Case Study VI: Unity power factor, the minor sections are 600 m, 550 m, and 475 m. Faults are created at 0 m, 500 m, 600 m, 875 m, 1150 m, 1385 m, and 1625 m.
vii. Case Study VII: Similar to Case VI, however the power factor at three phases are: 1, 0.9, and 0.85, while the magnitude of the current remains the same as a balanced case.

To verify the analytical results on single point grounded cable at he beginning, experiments were performed on 15 m long cable (all phases are of the same length). The healthy condition grounding current is measured for a balanced load having power factor one and is mentioned as an ideal case study. Two different case studies (Case I and Case II) are considered and faults are created in five different locations for each of the above case studies. Case study I is of balanced load condition of each phase having power factor one, while in case study II, the power factor at three phases are 1, 0.9, and 0.85, while the magnitude of the current remains the same as a balanced case, faults are created in the phase having power factor 1.

To verify the analytical results on single point grounded cable at the middle, the experiments were performed on a 15 m long three-phase cable (all phases are of the same length), grounding at 7.5 m (at the middle). To validate the analytical results three case studies (Case I, II, and III) are considered. All three case studies have balanced load and power factor one. In cases I, II, and III, the system is grounded at 7.5 m, 5 m, and 10 m respectively. Faults are created at seven different locations for each of the three case studies.

To verify the analytical results on two point grounded cable, The experiments were performed on a 15 m long three-phase cable (all phases are of the same length), to measure the healthy condition grounding current for an ideal case study. To validate the analytical results five case studies (Case I, II, III, IV, and V) are considered. Faults are created at five different locations in each case study. Cases I-IV have have balanced load of power factor one in each phase. In case I, only one major section is considered between source and load. In case II-IV, three major sections are considered between source to load. Fault is created at the middle, adjacent to the source end, and adjacent to the load end major section for cases II, III, and IV respectively. Case V is similar to case I, however, the power factor at three phases are 1, 0.9, and 0.85, while the magnitude of the current remains the same as a balanced case, faults are created in the phase having power factor 1.

Apart from the experimental cable, which was of limited length, voltage, and current supply, the simulation was performed on MATLAB SIMULINK. The operating voltage and current in the simulated cable are 220 kV and 550 A, having XLPE insulated material with a relative permittivity of 2.3 and thickness of 27 mm. The conductor radius is 21 mm and the metallic sheath is 6 mm. The cable is laid in a trefoil formation with r_{CS} and r_{SS} as 85 cm and 115 cm respectively. The value of grounding resistances RG1 and RG2 is 0.262. The fault resistance is considered of magnitude 3 mΩ for each case studies.

Simulation on a single point bonded cable at the beginning were performed on a three-phase 500 m long cable (all phases are of the same length). Healthy condition grounding current is measured for a load having power factor 1 and is mentioned as ideal case study. Two case study (Case I and II) are considered similar to the practical case of single point bonded cable.

Simulation on a single point bonded cable at the middle were performed on a 500 m long three-phase cable (all phases are of the same length), grounding at 250 m (at the middle). To estimate the location of SG fault, three case study (Case I, II, and III) are considered of balanced load having power after one, while grounded is made at 250 m, 200 m and in 300 m.

Simulation on a two point bonded cable were performed on a 500 m long three-phase cable (all phases are of the same length), to measure the healthy condition grounding current for an ideal case study. Similar to practical case, five case studies (Case I, II, III, IV, and V) are having similar features to the practical case of two point bonded cable.

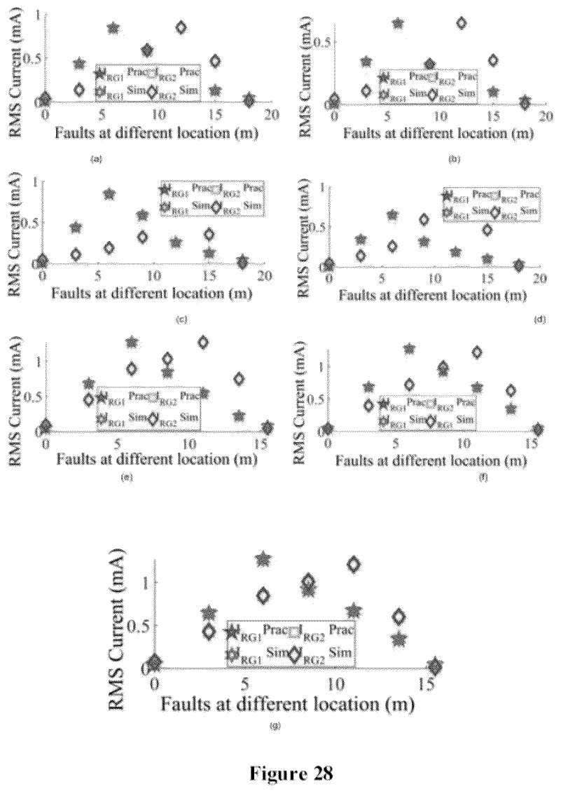

Now referring to FIG. 28, FIG. 28 illustrates the measured faults current at RG₁ and RG₂ for different practical case studies (a) Case I, (b) Case II, (c) Case III, (d) Case IV (e) Case V (f) Case VI (g) Case VII.

Analytically obtained the range of grounding currents (I_{RG1} and I_{RG2}) using equation no (25)-(26), or (29)-(30), or (33)-(34) for faults at different sections for seven different case studies is presented in Table I as mentioned above. The measured and simulated fault current at RG₁ and RG₂ for faults at different locations is shown in FIG. 28. After obtaining the measured current and comparing it with the range of values from Table I, the faults at the particular section are determined. Based on the particular section, where equation no (27) or (28), (31) or (33), (35) or (36) is applied to obtain its location. The accuracy of the proposed method (1200) for the different case study are shown in Table II.

TABLE I

| | 1^{st} Minor | | 2^{nd} Minor | | 3^{rd} Minor | |
|---|---|---|---|---|---|---|
| | section rms | | section rms | | section rms | |
| | current (mA) | | current (mA) | | current (mA) | |
| Cases | I_{RG1} | I_{RG2} | I_{RG1} | I_{RG2} | I_{RG1} | I_{RG2} |
| 1 | [0, 0.841) | [0.044, 0.256) | [0.841, 0.256) | [0.256, 0.841) | [0.256, 0.044] | [0.841, 0] |
| 2 | [0, 0.646) | [0.034, 0.186) | [0.646, 0.186) | [0.186, 0.646) | [0.186, 0.034] | [0.646, 0] |
| 3 | [0, 0.841) | [0.034, 0.186) | [0.841, 0.256) | [0.186, 0.646) | [0.256, 0.044) | [0.841, 0] |
| 4 | [0, 0.646) | [0.044, 0.256) | [0.646, 0.186) | [0.256, 0.841) | [0.186, 0.034] | [0.841, 0] |
| 5 | [0.045, 1.268) | [0.086, 0.866) | [1.268, 0.541) | [0.866, 1.262) | [0.541, 0.076] | [1.262, 0.043] |
| 6 | [0.047, 1.271) | [0.038, 0.715) | [1.271, 0.674) | [0.715, 1.215) | [0.674, 0.048] | [1.215, 0.021] |
| 7 | [0.046, 1.269) | [0.071, 0.841) | [1.269, 0.669) | [0.841, 1.206) | [0.669, 0.041] | [1.206, 0.014] |

TABLE II

| | Actual | Estimated | Estimated | Accuracy | Accuracy |
|---|---|---|---|---|---|
| | Location | location | location | I_{RG1} | I_{RG2} |
| Cases | (m) | A/c to I_{RG1} | A/c to I_{RG2} | (%) | (%) |
| 1 | 0 | 0.03 | 0.06 | — | — |
| | 3 | 2.97 | 2.93 | 99 | 97.66 |
| | 6 | 5.95 | 5.94 | 99.16 | 99.00 |
| | 9 | 8.92 | 8.93 | 99.11 | 99.22 |
| | 12 | 11.90 | 11.93 | 99.16 | 99.41 |
| | 15 | 14.91 | 14.95 | 99.4 | 99.66 |
| | 18 | 17.93 | 17.96 | 99.61 | 99.77 |
| 2 | 0 | 0.05 | 0.07 | — | — |
| | 3 | 2.96 | 2.91 | 98.66 | 97.00 |
| | 6 | 5.97 | 5.94 | 99.50 | 99.00 |
| | 9 | 8.94 | 8.95 | 99.33 | 99.44 |
| | 12 | 11.91 | 11.96 | 99.25 | 99.66 |
| | 15 | 14.93 | 14.94 | 99.53 | 99.60 |
| | 18 | 17.90 | 17.96 | 99.44 | 99.77 |
| 3 | 0 | 0.04 | 0.08 | — | — |
| | 3 | 2.98 | 2.94 | 99.33 | 98.00 |
| | 6 | 5.96 | 5.91 | 99.33 | 98.50 |
| | 9 | 8.95 | 8.97 | 99.44 | 99.66 |
| | 12 | 11.91 | 11.94 | 99.25 | 99.50 |
| | 15 | 14.91 | 14.93 | 99.40 | 99.53 |
| | 18 | 17.93 | 17.96 | 99.61 | 99.77 |
| 4 | 0 | 0.05 | 0.07 | — | — |
| | 3 | 2.95 | 2.90 | 98.33 | 96.66 |
| | 6 | 5.96 | 5.93 | 99.33 | 98.83 |
| | 9 | 8.94 | 8.96 | 99.33 | 99.55 |
| | 12 | 11.91 | 11.94 | 99.25 | 99.50 |
| | 15 | 14.93 | 14.96 | 99.53 | 99.73 |
| | 18 | 17.93 | 17.97 | 99.61 | 99.83 |
| 5 | 0 | 0.05 | 0.06 | — | — |
| | 3 | 2.96 | 2.94 | 98.66 | 98.00 |
| | 6 | 5.96 | 5.91 | 99.33 | 98.50 |
| | 9 | 8.93 | 8.95 | 99.22 | 99.44 |
| | 12 | 11.90 | 11.93 | 99.16 | 99.42 |
| | 15 | 14.89 | 14.93 | 99.26 | 99.53 |
| | 18 | 17.91 | 17.95 | 99.50 | 99.72 |
| 6 | 0 | 0.04 | 0.05 | — | — |
| | 3 | 2.95 | 2.91 | 98.33 | 97 |
| | 6 | 5.96 | 5.93 | 99.33 | 98.83 |
| | 8.5 | 8.45 | 8.46 | 99.41 | 99.52 |
| | 11 | 10.91 | 10.94 | 99.18 | 99.45 |
| | 13.5 | 13.41 | 13.46 | 99.33 | 99.70 |
| | 15.5 | 15.42 | 15.46 | 99.48 | 99.74 |
| 7 | 0 | 0.05 | 0.07 | — | — |
| | 3 | 2.96 | 2.93 | 98.66 | 97.67 |
| | 6 | 5.95 | 5.94 | 99.16 | 99.00 |
| | 8.5 | 8.44 | 8.46 | 99.29 | 99.53 |
| | 11 | 10.93 | 10.96 | 99.36 | 99.63 |
| | 13.5 | 13.43 | 13.44 | 99.48 | 99.55 |
| | 15.5 | 15.42 | 15.48 | 99.48 | 99.87 |

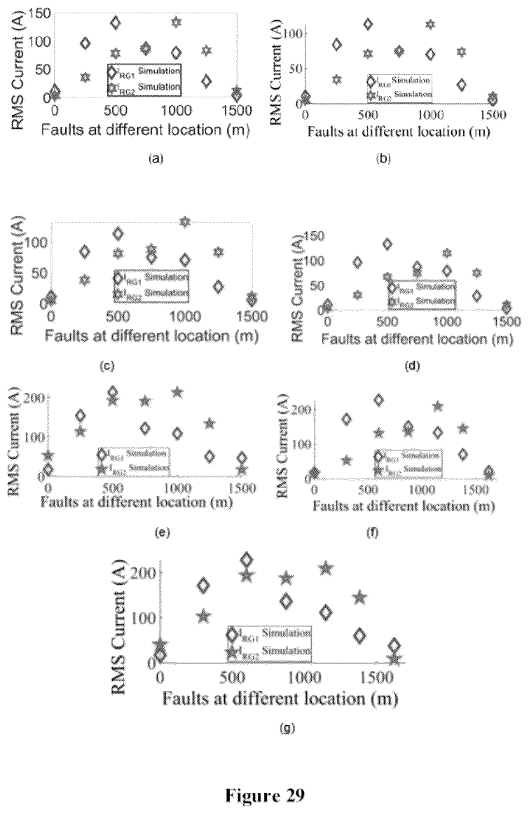

Now referring to FIG. 29, FIG. 29 illustrates the measured faults current at RG₁ and RG₂ for different simulated case study (a) Case I, (b) Case II, (c) Case III, (d) Case IV (e) Case V (f) Case VI (g) Case VII.

Analytically obtained the range of grounding currents (I_{RG1} and I_{RG2}) using equation no (25)-(26), or (29)-(30), or (33)-(34) is presented in Table III for seven different case studies as mentioned in section IV. Simulated faults current at RG₁ and RG₂ for faults at different locations is shown in FIG. 29. After obtaining the measured current and comparing it with the range of values from Table III, the faults at the particular section are determined. Based on the particular section, where equation no (27)-(28), (31)-(32), (35)-(36) is applied to obtain its location. The accuracy of the proposed method (1200) for different cases and different locations is shown in Table IV.

TABLE III

| | 1^{st} Minor | | 2^{nd} Minor | | 3^{rd} Minor | |
|---|---|---|---|---|---|---|
| | section rms | | section rms | | section rms | |
| | current (A) | | current (A) | | current (A) | |
| Cases | I_{RG1} | I_{RG2} | I_{RG1} | I_{RG2} | I_{RG1} | I_{RG2} |
| 1 | [0, 131.44) | [2.38, 77.41) | [131.44, 78.36) | [77.41, 132.22) | [78.36, 2.63] | [132.22, 0] |
| 2 | [0, 113.01) | [5.17, 70.85) | [113.01, 69.97) | [70.85, 112.51) | [69.97, 5.01] | [112.51, 0] |
| 3 | [0, 131.44) | [5.17, 70.85) | [131.44, 78.36) | [70.85, 112.51) | [78.36, 2.63] | [112.51, 0] |
| 4 | [0, 113.01) | [2.38, 77.41) | [113.01, 69.97) | [77.41, 132.22) | [69.97, 5.01] | [132.22, 0] |
| 5 | [17.14, 212.99) | [52.72, 192.21) | [212.99, 108.36) | [192.21, 212.96) | [108.36, 46.40] | [212.96, 17.24] |
| 6 | [17.23, 227.12) | [16.25, 131.32) | [227.12, 132.72) | [131.32, 208.50) | [132.72, 20.97] | [208.50, 8.64] |
| 7 | [17.11, 227.47) | [40.50, 193.06) | [227.47, 111.32) | [193.06, 208.51) | [111.31, 37.89] | [208.51, 8.64] |

TABLE IV

| | Actual | Estimated | Estimated | Accuracy | Accuracy |
|---|---|---|---|---|---|
| | Location | location | location | I_{RG1} | I_{RG2} |
| Cases | (m) | A/c to I_{RG1} | A/c to I_{RG2} | (%) | (%) |
| 1 | 0 | 0 | 0.13 | — | — |
| | 250 | 249.54 | 249.41 | 99.81 | 99.76 |
| | 500 | 499.57 | 499.18 | 99.91 | 99.84 |
| | 750 | 749.24 | 749.22 | 99.89 | 99.90 |
| | 1000 | 999.15 | 999.22 | 99.91 | 99.92 |
| | 1250 | 1249.54 | 1249.81 | 99.96 | 99.98 |
| | 1300 | 1498.74 | 1300 | 99.91 | 100 |
| 2 | 0 | 0 | 0.11 | — | — |
| | 250 | 249.71 | 249.40 | 99.88 | 99.76 |
| | 500 | 499.85 | 499.14 | 99.97 | 99.83 |
| | 750 | 749.54 | 749.68 | 99.94 | 99.96 |
| | 1000 | 999.23 | 999.69 | 99.92 | 99.97 |
| | 1250 | 1249.10 | 1249.66 | 99.93 | 99.97 |
| | 1300 | 1499.24 | 1300 | 99.95 | 100 |
| 3 | 0 | 0 | 0.13 | — | — |
| | 250 | 249.74 | 249.47 | 99.89 | 99.79 |
| | 500 | 499.87 | 499.21 | 99.97 | 99.84 |
| | 750 | 749.13 | 749.31 | 99.88 | 99.91 |
| | 1000 | 999.44 | 999.81 | 99.94 | 99.98 |
| | 1250 | 1249.36 | 1249.54 | 99.95 | 99.96 |
| | 1300 | 1498.87 | 1300 | 99.92 | 100 |
| 4 | 0 | 0 | 0.17 | — | — |
| | 250 | 249.31 | 249.56 | 99.72 | 99.82 |
| | 500 | 499.11 | 499.05 | 99.82 | 99.81 |
| | 750 | 749.85 | 749.80 | 99.98 | 99.97 |
| | 1000 | 999.41 | 999.53 | 99.94 | 99.95 |
| | 1250 | 1249.22 | 1249.67 | 99.94 | 99.97 |
| | 1300 | 1498.79 | 1300 | 99.92 | 100 |
| 5 | 0 | 0.15 | 0.17 | — | — |
| | 250 | 249.48 | 249.41 | 99.79 | 99.76 |
| | 500 | 499.14 | 498.95 | 99.83 | 99.79 |
| | 750 | 749.33 | 749.09 | 99.91 | 99.87 |
| | 1000 | 999.17 | 999.24 | 99.92 | 99.92 |
| | 1250 | 1248.91 | 1249.54 | 99.91 | 99.96 |
| | 1300 | 1499.21 | 1499.35 | 99.95 | 99.96 |
| 6 | 0 | 0.21 | 0.23 | — | — |
| | 500 | 299.45 | 299.15 | 99.82 | 99.72 |
| | 600 | 599.26 | 599.07 | 99.87 | 99.84 |
| | 875 | 873.97 | 874.01 | 99.88 | 99.89 |
| | 1150 | 1149.16 | 1149.25 | 99.92 | 99.93 |
| | 1385 | 1384.02 | 1384.17 | 99.93 | 99.94 |
| | 1625 | 1624.56 | 1624.74 | 99.97 | 99.98 |
| 7 | 0 | 0.22 | 0.24 | — | — |
| | 500 | 298.97 | 298.41 | 99.66 | 99.47 |
| | 600 | 599.67 | 599.47 | 99.95 | 99.91 |
| | 875 | 874.18 | 874.22 | 99.91 | 99.91 |
| | 1150 | 1148.24 | 1149.46 | 99.85 | 99.95 |
| | 1385 | 1384.22 | 1384.59 | 99.94 | 99.97 |
| | 1625 | 1623.89 | 1624.44 | 99.931 | 99.96 |

The healthy condition grounding current compared with analytically obtained values (14), (15) or (16), (18) for different types of bonding for the practical case study cable is presented in Table V while the simulation results compared with analytically obtained values are presented in Table VI. In Table V, Accuracy I and II, are the analytical results compared with measured and simulated study. An ideal case study is considered for both the practical and simulation cases.

TABLE V

| | Measured | Simulated | | | |
|---|---|---|---|---|---|
| | Current | Current | Analytical | Accuracy | Accuracy |
| Type | (R_{GS}) (mA) | (R_{GS}) (mA) | current | 1 (%) | 2 (%) |
| 1 | 1.0296 | 1.0298 | 1.0297 | 99.99 | 99.99 |
| 2 | 0.2341 | 0.2340 | 0.2339 | 99.98 | 99.95 |
| 3 | 0.2328 | 0.2327 | 0.2326 | 99.98 | 99.96 |

TABLE VI

| Type | Simulated Current (R_{GS}) | Analytical current | Accuracy (%) |
|---|---|---|---|
| 1 | 41.2568 | 41.2563 | 99.95 |
| 2 | 0.4155 | 0.4149 | 99.94 |
| 3 | 0.3974 | 0.3975 | 99.99 |

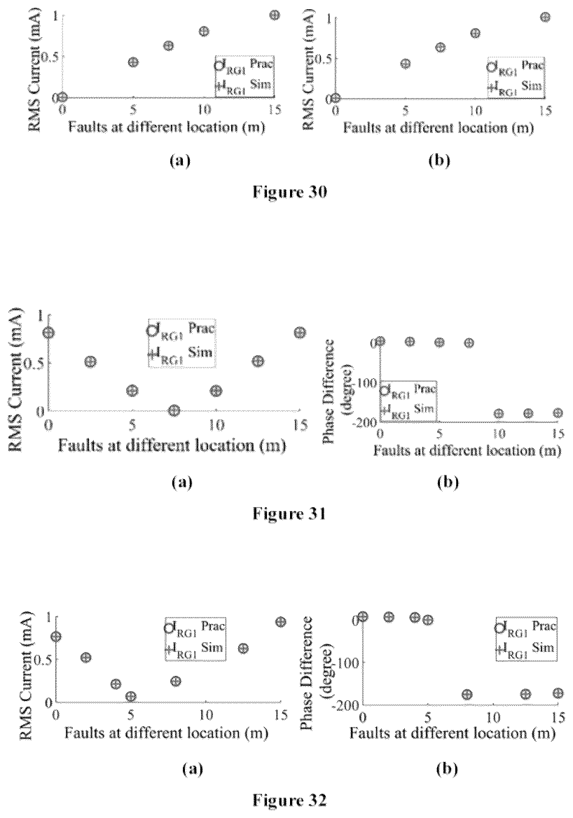

The measured and simulation results of two case studies of grounding current obtained for faults at different locations are shown in FIG. 30 (a) and FIG. 30 (b). After obtaining the measured current, the faults at the particular locations are determined using (37). The accuracy of the proposed method for different case studies is shown in Table VIL.

TABLE VII

| | | Estd location A/c | |
|---|---|---|---|
| Cases | Actual Location (m) | to measured I_{RG1} | Accuracy I_{RG1} (%) |
| 1 | 0 | 0 | — |
| | 5 | 4.9927 | 99.27 |
| | 7.5 | 7.4910 | 99.88 |
| | 10 | 9.9849 | 98.49 |
| | 15 | 14.9786 | 97.86 |
| 2 | 0 | 0 | — |
| | 5 | 4.9915 | 99.15 |
| | 7.5 | 7.4886 | 99.84 |
| | 10 | 9.9874 | 98.74 |
| | 15 | 14.9777 | 97.77 |

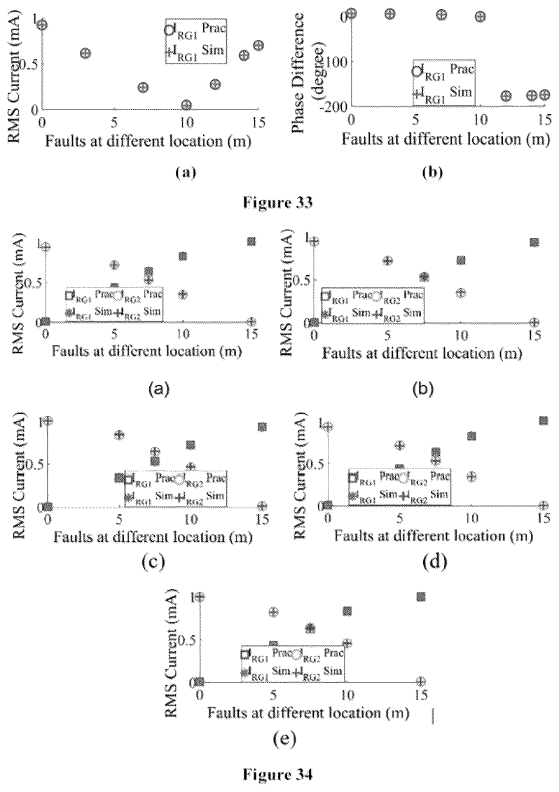

The measured and simulation results of three case studies of grounding current (magnitude and phase) obtained for faults at different locations are shown in FIG. 31, FIG. 32, and FIG. 33 . . . . After obtaining the measured current, the faults at the particular are determined using (38) and (39). The accuracy of the proposed method for different case studies is shown in

TABLE VIII

| | | Estd location A/c to | |
|---|---|---|---|
| Cases | Actual Location (m) | measured I_{RG1} | Accuracy I_{RG1} (%) |
| 1 | 0 | 0.0074 | — |
| | 2.5 | 2.4985 | 99.94 |
| | 5 | 4.9716 | 99.43 |
| | 7.5 | 7.4969 | 99.95 |
| | 10 | 9.9846 | 99.84 |
| | 12.5 | 12.4875 | 99.90 |
| | 15 | 14.8969 | 99.31 |
| 2 | 0 | 0.0076 | — |
| | 2 | 1.9806 | 99.03 |
| | 4 | 3.9764 | 99.41 |
| | 5 | 4.9930 | 99.86 |
| | 8 | 7.9696 | 99.62 |
| | 12.5 | 12.4012 | 99.21 |
| | 15 | 14.8620 | 99.08 |
| 3 | 0 | 0.0082 | — |
| | 3 | 2.9694 | 98.98 |
| | 7 | 6.9482 | 99.26 |
| | 10 | 9.9840 | 99.84 |
| | 12 | 11.9556 | 99.63 |
| | 14 | 13.8964 | 99.26 |
| | 15 | 14.8530 | 99.02 |

The measured and simulation results of five case studies of grounding current obtained for faults at different locations are shown in FIG. 34. After obtaining the measured current, the faults at the particular locations are determined using (40) or (41). The accuracy of the proposed method for different case studies is shown in Tablei IX.

TABLE IX

| | | Estd | Estd | | |
|---|---|---|---|---|---|
| | | location | location | | |
| | Actual | A/c to | A/c to | | |
| | Location | measured | measured | Accuracy | Accuracy |
| Cases | (m) | I_{RG1} | I_{RG2} | I_{RG1} (%) | I_{RG2} (%) |
| 1 | 0 | 0.0013 | 0.0019 | — | — |
| | 5 | 4.9846 | 4.9811 | 99.69 | 99.62 |
| | 7.5 | 7.4815 | 7.4906 | 99.75 | 99.87 |
| | 10 | 9.8569 | 9.8647 | 98.57 | 98.64 |
| | 15 | 14.7126 | 14.9815 | 98.08 | 99.87 |
| 2 | 0 | 0.0009 | 0.0022 | — | — |
| | 5 | 4.9865 | 4.9814 | 99.73 | 99.62 |
| | 7.5 | 7.4903 | 7.4918 | 99.87 | 99.89 |
| | 10 | 9.8685 | 9.8589 | 98.68 | 98.58 |
| | 15 | 14.7226 | 14.9788 | 98.15 | 99.85 |
| 3 | 0 | 0.0011 | 0.0019 | — | — |
| | 5 | 4.9853 | 4.9810 | 99.71 | 99.62 |
| | 7.5 | 7.4914 | 7.4911 | 99.88 | 99.88 |
| | 10 | 9.8721 | 9.8784 | 98.72 | 98.78 |
| | 15 | 14.7197 | 14.9810 | 98.13 | 99.87 |
| 4 | 0 | 0.0013 | 0.0022 | — | — |
| | 5 | 4.9891 | 4.9887 | 99.78 | 99.77 |
| | 7.5 | 7.4876 | 7.4897 | 99.83 | 99.86 |
| | 10 | 9.8957 | 9.8955 | 98.95 | 98.95 |
| | 15 | 14.7138 | 14.9806 | 98.09 | 99.87 |
| 5 | 0 | 0.0014 | 0.0023 | — | — |
| | 5 | 4.9826 | 4.9806 | 99.65 | 99.61 |
| | 7.5 | 7.4806 | 7.4893 | 99.74 | 99.85 |
| | 10 | 9.8722 | 9.8781 | 98.72 | 98.78 |
| | 15 | 14.7116 | 14.9713 | 98.07 | 99.80 |

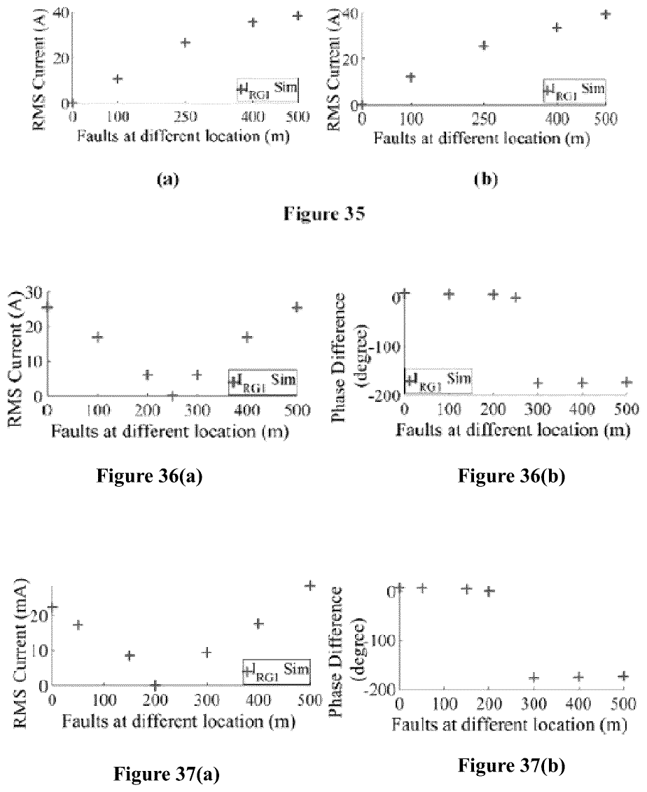

The simulation results of two case studies of grounding current obtained for faults at different locations for single-point bonded cables are shown in FIG. 35. The location of the SG fault is determined using (37). The accuracy of the proposed method for different case studies is shown in Table X.

TABLE X

| | | Estd location | |
|---|---|---|---|
| Cases | Actual Location (m) | A/c to I_{RG1} | Accuracy I_{RG1} (%) |
| 1 | 0 | 0 | — |
| | 100 | 99.9948 | 99.48 |
| | 250 | 249.9974 | 99.74 |
| | 400 | 399.9961 | 99.61 |
| | 500 | 499.9953 | 99.53 |
| 2 | 0 | 0 | — |
| | 100 | 99.9926 | 99.26 |
| | 250 | 249.9915 | 99.15 |
| | 400 | 399.9918 | 99.18 |
| | 500 | 499.9907 | 99.07 |

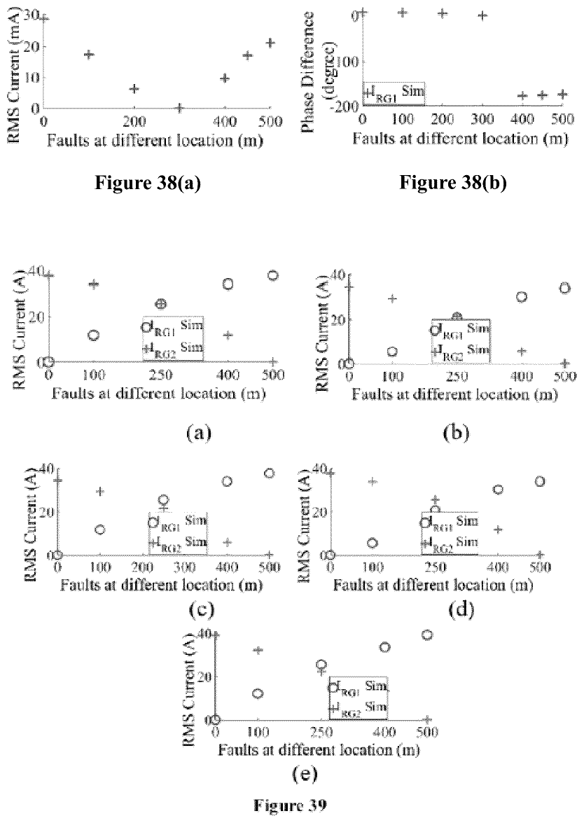

Similar to the practical case, simulation results of three case studies of grounding current (magnitude and phase) obtained for faults at different locations are shown in FIG. 36, FIG. 37, and FIG. 38. The faults at the particular location are determined using (38) or (39). The accuracy of the proposed method for different case studies is shown in Table XI.

TABLE XI

| | | Estd location | |
|---|---|---|---|
| Cases | Actual Location (m) | A/c to I_{RG1} | Accuracy I_{RG1} (%) |
| 1 | 0 | 0.0145 | — |
| | 100 | 99.9124 | 99.91 |
| | 200 | 198.2451 | 99.12 |
| | 250 | 250 | 100 |
| | 500 | 299.4759 | 99.82 |
| | 400 | 399.1478 | 99.78 |
| | 500 | 496.9857 | 99.39 |
| 2 | 0 | 0.0148 | — |
| | 50 | 49.95 | 99.90 |
| | 150 | 148.845 | 99.23 |
| | 200 | 200 | 100 |
| | 500 | 299.13 | 99.71 |
| | 400 | 399 | 99.75 |
| | 500 | 496.1 | 99.22 |
| | 0 | 0.0146 | — |
| 3 | 100 | 99.89 | 99.89 |
| | 200 | 198.62 | 99.31 |
| | 500 | 500 | 100 |
| | 400 | 399.44 | 99.86 |
| | 450 | 446.895 | 99.31 |
| | 500 | 495.95 | 99.19 |

Similar to the practical case, simulation results of five case studies of grounding current obtained for faults at different locations are shown in FIG. 39. The faults at the particular location are determined using (40) or (41). The accuracy of the proposed method for different case studies is shown in Table XII.

TABLE XII

| | Actual | Estd | Estd | | |
|---|---|---|---|---|---|
| | Location | location | location | Accuracy | Accuracy |
| Cases | (m) | A/c to I_{RG1} | A/c to I_{RG2} | I_{RG1} (%) | I_{RG2} (%) |
| 1 | 0 | 0 | 0.09041 | — | — |
| | 100 | 99.9961 | 99.9886 | 99.61 | 98.86 |
| | 250 | 249.9938 | 249.9942 | 99.38 | 99.42 |
| | 400 | 399.9882 | 399.9989 | 98.82 | 99.89 |
| | 500 | 499.9866 | 500 | 98.66 | 100 |
| 2 | 0 | 0 | 0.0915 | — | — |
| | 100 | 99.9971 | 99.9874 | 99.71 | 98.74 |
| | 250 | 249.9913 | 249.9911 | 99.13 | 99.11 |
| | 400 | 399.9877 | 399.9969 | 98.77 | 99.69 |
| | 500 | 499.9846 | 500 | 98.46 | 100 |
| 3 | 0 | 0 | 0.0947 | — | — |
| | 100 | 99.9969 | 99.9867 | 99.69 | 98.67 |
| | 250 | 249.9921 | 249.9932 | 99.21 | 99.32 |
| | 400 | 399.988 | 399.9965 | 98.80 | 99.65 |
| | 500 | 499.9854 | 500 | 98.54 | 100 |
| 4 | 0 | 0 | 0.0945 | — | — |
| | 100 | 99.9972 | 99.9870 | 99.72 | 98.70 |
| | 250 | 249.9917 | 249.9927 | 99.17 | 99.27 |
| | 400 | 399.9884 | 399.9968 | 98.84 | 99.68 |
| | 500 | 499.9851 | 500 | 98.51 | 100 |
| 5 | 0 | 0 | 0.1721 | — | — |
| | 100 | 99.9963 | 99.9868 | 99.63 | 98.68 |
| | 250 | 249.9907 | 249.9923 | 99.07 | 99.23 |
| | 400 | 399.9875 | 399.9988 | 98.75 | 99.88 |
| | 500 | 499.9844 | 500 | 98.44 | 100 |

Some embodiments, the ground-to-sheath faults for a test cable can be located with an uncertainty of ±1.76 m. irrespective of the location of the fault in a CB cable. (whether the fault is at the beginning, middle, or at the extreme end) or balanced or unbalanced condition defects.

Some embodiments, the ground-to-sheath faults for a test cable can be located with an uncertainty of ±0.15 m, irrespective of the location of the fault in a non cross bonded cable, (whether the fault is at the beginning, middle, or at the extreme end) or balanced or unbalanced condition defects.

Some embodiments the pinpoint location of an SG fault in a CB (111) power cable is achieved by measuring the grounding current in online conditions and then using these currents in the proposed analytical formulae. Although the identification, of the presence of sheath fault is accomplished from the measured sheath current at the link boxes, however, the pinpoint location at any arbitrary position is still unachievable. Along with this, installation of the current sensor into the link during operational conditions can prove to be hazardous for the maintenance workers, due to the presence of sudden switching impulses. Therefor the proposed method (1200) and (1300) is not only safe but also reduces the cost of installing the sensor in the CB (111) link box.

Some embodiments, a code has been made in MATLAB Simulink, where the measured data using an ammeter can be incorporated and the software will able to detect and identify the location of the SG fault. The applicability of the proposed methods (1200) and (1300) to identify the location of an SG defect is justified by the practical test on a test cable in the laboratory and simulation studies. The proposed method (1200) and (1300) are shown to have an uncertainty of less than 0.07 m for a CB cable and 0.14 m for laboratory cable and 1.76 m for on-field cable, irrespective of the location, dimension, or balanced or unbalanced condition. It is believed that the outcome is useful for the utility sector to find the location of the SG fault during online conditions, to prevent premature breakdown.

In some embodiment, the system (100) identifies and locate the inception of SG fault can further be extended to different types of bonding. (single point as well as two points bonding).

In some embodiment, the system (100) can estimate the locations of inception of SG faults in balanced conditions as well as in all unbalanced conditions (unbalance in load (102), voltage, phase voltage, length, or any physical structure of the cable).

In some embodiment, the system (100) estimates the value of sheath current during healthy and faulty conditions, using the cable system parameters (electrical parameters either obtained analytically or measured through experiments) and conductor voltage and current and phase angle.

In some embodiment, the system (100) and method (1200) to detect the inception or onset of a sheath-to-ground (SG) fault at any arbitrary location in underground cross-bonded (CB) cables during online mode by using earthing currents.

In some embodiment, the systems (200), (300), and (400) and method (1300) to detect the inception or onset of a sheath-to-ground (SG) fault at any arbitrary location in underground non-cross-bonded cables during online mode by using earthing currents.

Exemplary embodiments discussed above may provide certain advantages. Though not required to practice aspects of the disclosure, the advantages may include those provided by the following features.

Some embodiment of the methods (1200) and (1300) are less susceptible to noise.

Some embodiment of the methods (1200) and (1300) are easy to implement and time efficient.

Some embodiment of the methods (1200) and (1300) able to locate SG fault in any unbalanced condition i.e., change in the length of the minor section, or variation of load (102) current or power factor, phase voltage will not alter its accuracy.

Some embodiment of the method (1200) and (1300) the ground-to-sheath faults for a test cable can be located with an uncertainty of ±0.08 m, irrespective of the location of the fault, whether the fault is at the beginning, middle, or at the extreme end or balanced or unbalanced condition.

Some embodiment of the experimental result of the prediction was extremely good and had an accuracy of more than 96.66%. The result was verified using both simulation and practical high-voltage cable.

Following is a list of elements and reference numerals used to explain various embodiments of the present subject matter.

| Reference | |
|---|---|
| Numeral | Element Description |
| 100 | CB System |
| 101 | Three-phase source voltage (V_{R}, V_{Y}, and V_{B}) in CB |
| | cable |
| 102 | Loads (L_{R}, L_{Y}, and L_{B}) in CB cable |
| 103 | Grounding Resistances (RG₁, RG₂, RG₁′, RG₂′, RG₁″, |
| | and RG₂″) |
| 104 | Minor section 1 |
| 105 | Minor section 2 |
| 106 | Minor section 3 |
| 107 | Sheath voltage limiter (SVLs) |
| 108 | Phase R in CB cable |
| 109 | Phase Y in CB cable |
| 110 | Phase B in CB cable |
| 111 | Cross-bonded (CB) cable |
| 200 | Single point grounded at the beginning system |
| 201 | Grounding Resistances for single point grounded at the |
| | beginning |
| 202 | Three-phase source voltage (V_{R}, V_{Y}, and V_{B}) in single |
| | point grounded at the beginning cable |
| 203 | Loads (L_{R}, L_{Y}, and L_{B}) in single point grounded at the |
| | beginning cable. |
| 300 | Single point grounding at the middle system |
| 301 | Grounding Resistances for single point grounded at the |
| | middle |
| 302 | Three-phase source voltage (V_{R}, V_{Y}, and V_{B}) in single |
| | point grounded at the middle cable |
| 303 | Loads (L_{R}, L_{Y}, and L_{B}) in single point grounded at the |
| | middle cable |
| 401 | Two point grounding system |
| 402 | Grounding Resistances for two point grounded |
| 403 | Three-phase source voltage (V_{R}, V_{Y}, and V_{B}) in two point |
| | grounded cable |
| 404 | Loads (L_{R}, L_{Y}, and L_{B}) in single point grounded at the |
| | beginning cable |
| 500 | Circuit model of a major section of CB cable |
| 501 | Loop 1 (R₁-Y₂-B₃) |
| 502 | Loop 2 (Y₁-B₂-R₃) |
| 503 | Loop 3 (B₁-R₂-Y₃) |
| 1200 | Flowchart/method for a CB cable |
| 1201 | Measuring dimensional and electrical properties of the |
| | CB cable |
| 1202 | Measuring electrical properties of the grounding |
| | resistance |
| 1203 | Analytically obtaining grounding current range values for |
| | all minor section |
| 1204 | Cable is having SG fault in a CB cable |
| 1205 | Cable is not having SG fault in a CB cable |
| 1206 | Determining minor section having SG fault in the CB |
| | cable |
| 1207 | Estimating the location of SG fault by using grounding |
| | current value in the CB cable |
| 1300 | Flowchart/method for a non-crossbonded cable |
| 1301 | Measuring dimensional and electrical properties of the |
| | non-crossbonded cable |
| 1302 | Identify the types on bonding of the system |
| 1303 | Measuring conductor voltage, current and sheath sheath |
| | current in a non-crossbonded cable |
| 1304 | Analytically obtaining grounding current value for the |
| | particular type of bonding |
| 1305 | Cable is not having SG fault in a non-crossbonded cable |
| 1306 | Cable is having SG fault in a non-crossbonded cable |
| 1307 | Estimating the location of SG fault by using grounding |
| | current value in the non CB cable |

### EQUIVALENTS

With respect to the use of substantially any plural and/or singular terms herein, those having skill in the art can translate from the plural to the singular and/or from the singular to the plural as is appropriate to the context and/or application. The various singular/plural permutations may be expressly set forth herein for sake of clarity.

It will be understood by those within the art that, in general, terms used herein, and especially in the appended claims (e.g., bodies of the appended claims) are generally intended as “open” terms (e.g., the term “including” should be interpreted as “including but not limited to,” the term “having” should be interpreted as “having at least,” the term “includes” should be interpreted as “includes but is not limited to,” etc.). It will be further understood by those within the art that if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to inventions containing only one such recitation, even when the same claim includes the introductory phrases “one or more” or “at least one” and indefinite articles such as “a” or “an” (e.g., “a” and/or “an” should typically be interpreted to mean “at least one” or “one or more”); the same holds true for the use of definite articles used to introduce claim recitations. In addition, even if a specific number of an introduced claim recitation is explicitly recited, those skilled in the art will recognize that such recitation should typically be interpreted to mean at least the recited number (e.g., the bare recitation of “two recitations,” without other modifiers, typically means at least two recitations, or two or more recitations). Furthermore, in those instances where a convention analogous to “at least one of A, B, and C, etc.” is used, in general such a construction is intended in the sense one having skill in the art would understand the convention (e.g., “a system having at least one of A, B, and C” would include but not be limited to systems that have A alone, B alone, C alone, A and B together, A and C together, B and C together, and/or A, B, and C together, etc.). In those instances, where a convention analogous to “at least one of A, B, or C, etc.” is used, in general such a construction is intended in the sense one having skill in the art would understand the convention (e.g., “a system having at least one of A, B, or C” would include but not be limited to systems that have A alone, B alone, C alone, A and B together, A and C together, B and C together, and/or A, B, and C together, etc.). It will be further understood by those within the art that virtually any disjunctive word and/or phrase presenting two or more alternative terms, whether in the description, claims, or drawings, should be understood to contemplate the possibilities of including one of the terms, either of the terms, or both terms. For example, the phrase “A or B” will be understood to include the possibilities of “A” or “B” or “A and B.”

Although implementations for the system (100) and method (1200) of locating a sheath to ground faults in cross-bonded (CB) (111) cables have been described in language specific to structural features and/or methods, it is to be understood that the appended claims are not necessarily limited to the specific features described. Rather, the specific features are disclosed as examples of implementation for the system (100) and method (1200) of locating a sheath to ground faults in cross-bonded (CB) (111) cables.

Although implementations for the system ES (200), (300), (400) and method (1300) of locating a sheath to ground faults in non-crossbonded (CB) cables have been described in language specific to structural features and/or methods, it is to be understood that the appended claims are not necessarily limited to the specific features described. Rather, the specific features are disclosed as examples of implementation for the system (200), (300), (400) and method (1200) of locating a sheath to ground faults in non-crossbonded cables.

1. A system for identifying and locating a sheath to ground (SG) at any arbitrary position faults in an electrical cables during online condition comprising:
a high voltage cross-bonded (CB) power cable having 3 phases R, Y, B;
plurality of minor sections are configured to be formed from said CB power cable;
a metallic sheath of each phase is configured to be grounded at a grounding box through plurality of grounding resistances;
a system configured to measure the current from the grounding resistances;
a high voltage non-crossbonded power cable, a single point grounded at the beginning or end cable, single point grounded at the middle cable, and two point grounded d cable having 3 phases R, Y, B;
a metallic sheath of each phase is configured to be grounded at a grounding box through plurality of grounding resistances for different types of non-crossbonded cable, and;
a software processor configured to determine the analytical current of grounding resistances for a CB cable and compare with measured current to determine the minor section having SG fault; and
a software processor configured to determine the analytical current of grounding resistances for different types of non-crossbonded cable, and compare with measured current to determine the minor section having SG fault.

2. The system as claimed in claim 1, wherein the system is configured to locate the inception of SG fault for a CB cable and non-cross bonded cable (single point bonded at the beginning or at the end, single point bonding at the middle and two point bonded cable.

3. The system as claimed in claim 1, wherein the system is configured to locate the inception of SG faults in balanced conditions and unbalanced conditions.

4. The system as claimed in claim 1, wherein said minor sections are configured of three loops R₁-Y₂-B₃ (loop 1), Y₁-B₂-R₃ (loop 2), and B₁-R₂-Y₃ (loop 3) for a CB cable.

5. The system as claimed in claim 1, wherein said system is configured to determine the conductor impedance, sheath impedance, insulation capacitance, and conductance of the cables.

6. The system as claimed in claim 1, wherein said system is configured to detect the inception or onset of a sheath-to-ground (SG) fault at any arbitrary location in underground cross-bonded (CB) cables and non-crossbonded cable in real time by using earthing currents.

7. A method for locating a sheath to ground (SG) faults in cross-bonded (CB) cables comprising:
measuring the length of the minor section, dimension, and electrical properties of the cross-bonded cable (CB) to calculate different electrical parameters by predefined equation no to or measuring the above mentioned things experimentally;
measuring the operating phase voltage, phase current, and actual sheath current by predefined equation no from the grounding resistance of all phases (R, Y, and B) by utilizing current sensor;
analytically obtaining both the grounding current range of values for all minor sections by using equation no—or—or—;
comparing both the analytical grounding current and measured grounding current to determine the sheath to ground fault; and
determining the minor section having sheath fault by locating the fault analytically or either using any of the measured current values from equation no—or—or—.

8. A method for locating a sheath to ground (SG) faults in non-crossbonded cables comprising:
measuring the length of the minor section, dimension, and electrical properties of the non-cross-bonded cable to calculate different electrical parameters by predefined equation no to or measuring the above mentioned things experimentally;
Identify the type of bonding in the system, whether grounded at the beginning or end cable, single point grounded at the middle cable, and two point grounded d cable.
measuring the operating phase voltage, phase current, and actual sheath current by from the grounding resistance of all phases (R, Y, and B) by utilizing current sensor;
analytically obtaining both the grounding current range of values for non-crossbonded power cable by using equation no, —or;
comparing both the analytical grounding current and measured grounding current to determine whether the cable is having an SG or not.
determining the location of sheath fault by using the measured current values from equation no.
